(19) United States
(12) Patent Application Publication
(10) Pub. No.: US 2024/0241436 A1
(43) Pub. Date: Jul. 18, 2024

(54) DETERMINING MASK RULE CHECK VIOLATIONS AND MASK DESIGN

(71) Applicant: ASML NETHERLANDS B.V., Veldhoven (NL)

(72) Inventors: Xingyue PENG, San Jose, CA (US); Rafael C. HOWELL, Santa Clara, CA (US); Yen Wen LU, Saratoga, CA (US); Xiaorui CHEN, San Jose, CA (US)

(73) Assignee: ASML NETHERLANDS B.V., Veldhoven (NL)

(21) Appl. No.: 18/289,384

(22) PCT Filed: May 10, 2022
(86) PCT No.: PCT/EP2022/062691

§ 371 Date: Nov. 3, 2023

Related U.S. Application Data
(60) Provisional application No. 63/192,878, filed on May 25, 2021.

(51) Int. Cl. G03F 1/84; G03F 1/36; G06F 30/20

(52) U.S. Cl. CPC G03F 1/84; G06F 30/20; G03F 1/36

(57) ABSTRACT

Methods and systems for determining a mask rule check violation (MRC) associated with a mask feature using a detector having geometric properties corresponding to the MRC. The detector (e.g., elliptical shaped) is configured to include a curved portion to detect a curvature violation, include an enclosed area (e.g., a fully enclosed area or a partially enclosed area having an opening), include a predefined orientation axis configured to guide relative positioning of the detector with a mask feature, and include a length to detect a critical dimension violation. The orientation axis of the detector is aligned with a normal axis at a location on the mask feature. Based on the orientation axis aligned with the normal axis of the mask feature, an MRC violation is determined corresponding to a region of the mask feature that intersects the enclosed area.

### CROSS-REFERENCE TO RELATED APPLICATIONS

This application claims priority of U.S. application 63/192,878 which was filed on May 25, 2021 and which is incorporated herein in its entirety by reference.

### TECHNICAL FIELD

The description herein relates to a mechanism for determining mask rule check violations and mask design for photolithography masks to be employed in in semiconductor manufacturing.

### BACKGROUND

A lithographic projection apparatus can be used, for example, in the manufacture of integrated circuits (ICs). In such a case, a patterning device (e.g., a mask) may contain or provide a circuit pattern corresponding to an individual layer of the IC (“design layout”), and this circuit pattern can be transferred onto a target portion (e.g. comprising one or more dies) on a substrate (e.g., silicon wafer) that has been coated with a layer of radiation-sensitive material (“resist”), by methods such as irradiating the target portion through the circuit pattern on the patterning device. In general, a single substrate contains a plurality of adjacent target portions to which the circuit pattern is transferred successively by the lithographic projection apparatus, one target portion at a time. In one type of lithographic projection apparatuses, the circuit pattern on the entire patterning device is transferred onto one target portion in one go; such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the circuit pattern on the patterning device are transferred to one target portion progressively. Since, in general, the lithographic projection apparatus will have a magnification factor M (generally <1), the speed F at which the substrate is moved will be a factor M times that at which the projection beam scans the patterning device. More information with regard to lithographic devices as described herein can be gleaned, for example, from U.S. Pat. No. 6,046,792, incorporated herein by reference.

Prior to transferring the circuit pattern from the patterning device to the substrate, the substrate may undergo various procedures, such as priming, resist coating and a soft bake. After exposure, the substrate may be subjected to other procedures, such as a post-exposure bake (PEB), development, a hard bake and measurement/inspection of the transferred circuit pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

As noted, lithography is a central step in the manufacturing of ICs, where patterns formed on substrates define functional elements of the ICs, such as microprocessors, memory chips etc. Similar lithographic techniques are also used in the formation of flat panel displays, micro-electro mechanical systems (MEMS) and other devices.

As semiconductor manufacturing processes continue to advance, the dimensions of functional elements have continually been reduced while the number of functional elements, such as transistors, per device has been steadily increasing over decades, following a trend commonly referred to as “Moore's law”. At the current state of technology, layers of devices are manufactured using lithographic projection apparatuses that project a design layout onto a substrate using illumination from a deep-ultraviolet illumination source, creating individual functional elements having dimensions well below 100 nm, i.e., less than half the wavelength of the radiation from the illumination source (e.g., a 193 nm illumination source).

This process in which features with dimensions smaller than the classical resolution limit of a lithographic projection apparatus are printed, is commonly known as low-k₁ lithography, according to the resolution formula CD=k₁×W/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k₁ is an empirical resolution factor. In general, the smaller k₁ the more difficult it becomes to reproduce a pattern on the substrate that resembles the shape and dimensions planned by a circuit designer in order to achieve particular electrical functionality and performance. To overcome these difficulties, sophisticated fine-tuning steps are applied to the lithographic projection apparatus and/or design layout. These include, for example, but not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET). The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

### BRIEF SUMMARY

Disclosed herein is a mechanism for improving mask rule checks (MRC) related to mask designs, for example, having curvilinear mask features. The existing MRC techniques involve cutline-based violation detections. The existing techniques lack tuning capability and cannot accommodate different curvature shapes. Also, these techniques rely on heuristic rules applied at curvature regions of the mask features. Thus, existing techniques results in several false violations detection. The present disclosure provides detectors configured to determine MRC for curvilinear features. The detectors herein provide flexibility and high tuning capability to accommodate MRC for different curved shapes of the mask features. Using the detectors, improves the MRC violation detection with less false violations thereby speeding up the MRC violation determination. Also, mask designs can be improved based on information related to MRC violations detected by the detectors herein. This in turn improves the semiconductor manufacturing process that employs a mask designed based on information related to MRC violations, according to the present disclosure.

According to an embodiment of the present disclosure, a method for determining mask rule check violations associated with mask features is described. The method includes obtaining a detector having geometric properties corresponding to a mask rule check (MRC). The detector is configured to include a curved portion to detect a curvature violation, an enclosed area (e.g., a fully enclosed area or a partially enclosed area having an opening), a predefined orientation axis configured to guide relative positioning of the detector with a mask feature, and a length along the orientation axis to detect a critical dimension violation. The orientation axis of the detector is aligned with a normal axis at a location on the mask feature to cause the length of the detector to extend along the normal axis of the mask feature. Further, the method identifies, based on the orientation axis of the detector aligned with the normal axis of the mask feature, an MRC violation corresponding to a region of the mask feature that intersects the enclosed area. The aligning and geometry of the detector causes the detector to intersect the region of mask feature to identify the curvature violation, and/or the critical dimension violation.

In an embodiment, the detector is non-circular and has at least a first curved portion and a second curved portion, wherein the first curved portion has a first radius of curvature, where the second curved portion has a second radius of curvature, and where the first radius is different from the second radius. For example, the non-circular detector has an elliptical shape, wherein a radius of curvature is configured to detect a curvature violation and a length along an orientation axis is configured to detect a critical dimension violation.

In an embodiment, the curved portion of the detector has a shape and size corresponding to a curvature of a tip portion of the mask feature, and a minimum size of the mask feature defined by mask manufacturability check.

In an embodiment, the identifying step involves determining MRC violations including a curvature violation and a critical dimension violation based on the intersection of the detector with the mask feature at a single position. In an embodiment, MRC violations associated with a curvature violation and a space violation is determined based on intersection between at least two mask features at a single position.

In an embodiment, the method further involves performing a mask design to determine shape and size of mask features of the mask design by adopting a mask design process (e.g., OPC, mask optimization or SMO) to include MRC violation detection using one or more detectors herein.

According to an embodiment of the present disclosure, a method for determining a mask design for manufacturing a mask to be employed in a semiconductor manufacturing is described. The method involves simulating, using a design layout, a mask optimization process (e.g., SMO, OPC, etc.) to determine mask features for the mask design. The design layout corresponds to features to be printed on a semiconductor chip. Using a detector portions of the mask features that violate a mask rule check (MRC) is determined. The detector (e.g., elliptical shaped) is configured to have a curved portion, an enclosed area (e.g., fully or partially enclosed), and an orientation axis that is perpendicular to a point of the curved portion, the orientation axis for guiding an orientation of the detector with respect to a mask feature to detect MRC violations. Responsive to the portions of the mask feature violating the MRC, the corresponding portions of the mask features are modified to satisfy the MRC.

In an embodiment, the determining the portions of the mask features that violate the MRC involves obtaining the detector having geometric properties corresponding to the MRC; aligning the orientation axis with a normal axis of a location on a mask feature; and identifying, based on the orientation axis of the detector and the normal axis of the mask feature, the MRC violation corresponding to a region of the mask feature that intersects the enclosed area.

In an embodiment, the detector is a single detector configured to determine MRC violations including a curvature violation and a width violation associated with the mask feature. In an embodiment, the detector is a single detector configured to determine MRC violations associated with a curvature violation and a space violation between at least two mask features.

According to an embodiment, there is provided a non-transitory computer-readable medium for determining mask rule check violations associated with mask features, the medium comprising instructions stored therein that, when executed by one or more processors, cause operations including steps of the method herein.

### BRIEF DESCRIPTION OF THE DRAWINGS

FIG. 1 is a block diagram of various subsystems of a lithography system, according to an embodiment of the present disclosure.

FIG. 2 is a block diagram of simulation models corresponding to the subsystems in FIG. 1, according to an embodiment of the present disclosure.

FIG. 3A illustrates a mask rule check (MRC) performed on a Manhattan feature, according to an embodiment of the present disclosure.

FIG. 3B illustrates an MRC performed on a curvilinear feature, according to an embodiment of the present disclosure.

FIGS. 4 and 5 illustrate mask features having a rounded tip and a narrower tip, respectively, according to an embodiment of the present disclosure.

FIG. 6 is a flowchart of a method for determining mask features that violate MRC, according to an embodiment of the present disclosure.

FIGS. 7A-7F illustrate different type of detector, each detector having a particular shape and a particular orientation axis, according to an embodiment of the present disclosure.

FIG. 7G illustrates a geometry of the detector including a length configured to detect a size violation, according to an embodiment of the present disclosure.

FIG. 7H illustrates a detector having a partially enclosed area having an opening, according to an embodiment of the present disclosure.

FIG. 8A illustrates identifying of MRC violations associated with a mask feature by employing a circular detector, according to an embodiment of the present disclosure.

FIG. 8B illustrates identifying of MRC violations associated with a mask feature by employing a non-circular detector, according to an embodiment of the present disclosure.

FIG. 8C illustrates identifying of MRC violations associated with two mask features by employing a non-circular detector, according to an embodiment of the present disclosure.

FIG. 8D illustrates identifying of both curvature and size violation at a single location of a mask feature using a single detector, according to an embodiment of the present disclosure.

FIG. 9 is a flowchart of a method for determining a mask design based on detectors (e.g., of FIGS. 7B-7F), according to an embodiment of the present disclosure.

FIG. 10 is a flow diagram illustrating aspects of an example methodology of joint optimization/co-optimization, according to an embodiment of the present disclosure.

FIG. 11 shows an embodiment of a further optimization method, according to an embodiment of the present disclosure.

FIG. 12A, FIG. 12B and FIG. 13 show example flowcharts of various optimization processes, according to an embodiment of the present disclosure.

FIG. 14 is a block diagram of an example computer system, according to an embodiment of the present disclosure.

FIG. 15 is a schematic diagram of a lithographic projection apparatus, according to an embodiment of the present disclosure.

FIG. 16 is a schematic diagram of another lithographic projection apparatus, according to an embodiment of the present disclosure.

FIG. 17 is a more detailed view of the apparatus in FIG. 16, according to an embodiment of the present disclosure.

FIG. 18 is a more detailed view of the source collector module SO of the apparatus of FIG. 16 and FIG. 17, according to an embodiment of the present disclosure.

### DETAILED DESCRIPTION

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g., with a wavelength of 365, 248, 193, 157 or 126 nm) and EUV (extreme ultra-violet radiation, e.g., having a wavelength in the range of about 5-100 nm).

The term “optimizing” and “optimization” as used herein refers to or means adjusting a lithographic projection apparatus, a lithographic process, etc. such that results and/or processes of lithography have more desirable characteristics, such as higher accuracy of projection of a design layout on a substrate, a larger process window, etc. Thus, the term “optimizing” and “optimization” as used herein refers to or means a process that identifies one or more values for one or more parameters that provide an improvement, e.g., a local optimum, in at least one relevant metric, compared to an initial set of one or more values for those one or more parameters. “Optimum” and other related terms should be construed accordingly. In an embodiment, optimization steps can be applied iteratively to provide further improvements in one or more metrics.

Further, the lithographic projection apparatus may be of a type having two or more tables (e.g., two or more substrate table, a substrate table and a measurement table, two or more patterning device tables, etc.). In such “multiple stage” devices a plurality of the multiple tables may be used in parallel, or preparatory steps may be carried out on one or more tables while one or more other tables are being used for exposures. Twin stage lithographic projection apparatuses are described, for example, in U.S. Pat. No. 5,969,441, incorporated herein by reference.

The patterning device referred to above comprises, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between circuit devices (such as gates, capacitors, etc.) or interconnect lines, so as to ensure that the circuit devices or lines do not interact with one another in an undesirable way. One or more of the design rule limitations may be referred to as “critical dimensions” (CD). A critical dimension of a circuit can be defined as the smallest width of a line or hole or the smallest space between two lines or two holes. Thus, the CD determines the overall size and density of the designed circuit. Of course, one of the goals in integrated circuit fabrication is to faithfully reproduce the original circuit design on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include:
a programmable mirror array. An example of such a device is a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means. More information on such mirror arrays can be gleaned, for example, from U.S. Pat. Nos. 5,296,891 and 5,523,193, which are incorporated herein by reference.
a programmable LCD array. An example of such a construction is given in U.S. Pat. No. 5,229,872, which is incorporated herein by reference.

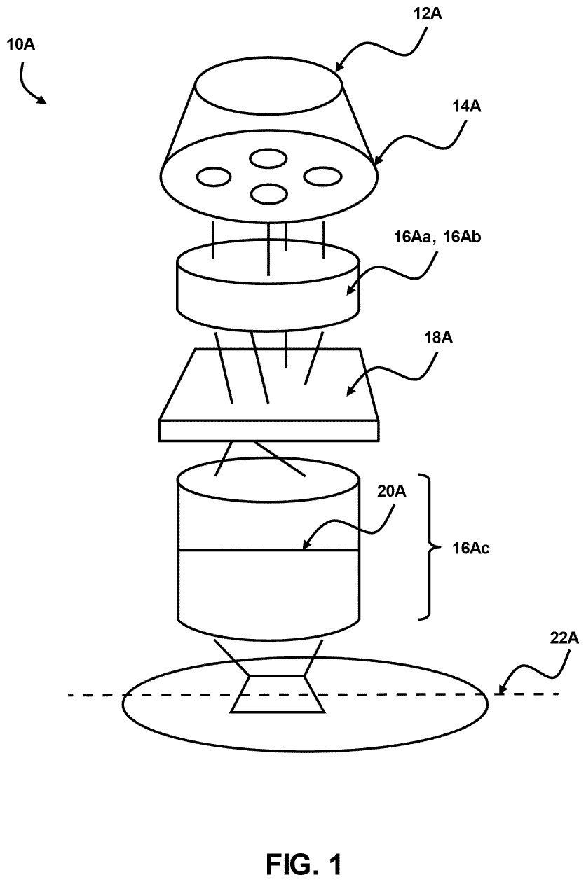

As a brief introduction, FIG. 1 illustrates an exemplary lithographic projection apparatus 10A. Major components are a radiation source 12A, which may be a deep-ultraviolet excimer laser source or other type of source including an extreme ultra violet (EUV) source (as discussed above, the lithographic projection apparatus itself need not have the radiation source), illumination optics which define the partial coherence (denoted as sigma) and which may include optics 14A, 16Aa and 16Ab that shape radiation from the source 12A; a patterning device 14A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin(Θₘₐₓ), n is the Index of Refraction of the media between the last element of projection optics and the substrate, and Θₘₐₓ is the largest angle of the beam exiting from the projection optics that can still impinge on the substrate plane 22A. The radiation from the radiation source 12A may not necessarily be at a single wavelength. Instead, the radiation may be at a range of different wavelengths. The range of different wavelengths may be characterized by a quantity called “imaging bandwidth.” “source bandwidth” or simply “bandwidth,” which are used interchangeably herein. A small bandwidth may reduce the chromatic aberration and associated focus errors of the downstream components, including the optics (e.g., optics 14A, 16Aa and 16Ab) in the source, the patterning device and the projection optics. However, that does not necessarily lead to a rule that the bandwidth should never be enlarged.

In an optimization process of a system, a figure of merit of the system can be represented as a cost function. The optimization process boils down to a process of finding a set of parameters (design variables) of the system that optimizes (e.g., minimizes or maximizes) the cost function. The cost function can have any suitable form depending on the goal of the optimization. For example, the cost function can be weighted root mean square (RMS) of deviations of certain characteristics (evaluation points) of the system with respect to the intended values (e.g., ideal values) of these characteristics; the cost function can also be the maximum of these deviations (i.e., worst deviation). The term “evaluation points” herein should be interpreted broadly to include any characteristics of the system. The design variables of the system can be confined to finite ranges and/or be interdependent due to practicalities of implementations of the system. In the case of a lithographic projection apparatus, the constraints are often associated with physical properties and characteristics of the hardware such as tunable ranges, and/or patterning device manufacturability design rules, and the evaluation points can include physical points on a resist image on a substrate, as well as non-physical characteristics such as dose and focus.

In a lithographic projection apparatus, a source provides illumination (i.e., radiation) to a patterning device and projection optics direct and shape the illumination, via the patterning device, onto a substrate. The term “projection optics” is broadly defined here to include any optical component that may alter the wavefront of the radiation beam. For example, projection optics may include at least some of the components 14A, 16Aa, 16Ab and 16Ac. An aerial image (AI) is the radiation intensity distribution at substrate level. A resist layer on the substrate is exposed and the aerial image is transferred to the resist layer as a latent “resist image” (RI) therein. The resist image (RI) can be defined as a spatial distribution of solubility of the resist in the resist layer. A resist model can be used to calculate the resist image from the aerial image, an example of which can be found in U.S. Patent Application Publication No. US 2009-0157360, the disclosure of which is hereby incorporated by reference in its entirety. The resist model is related only to properties of the resist layer (e.g., effects of chemical processes which occur during exposure, PEB and development). Optical properties of the lithographic projection apparatus (e.g., properties of the source, the patterning device and the projection optics) dictate the aerial image. Since the patterning device used in the lithographic projection apparatus can be changed, it is desirable to separate the optical properties of the patterning device from the optical properties of the rest of the lithographic projection apparatus including at least the source and the projection optics.

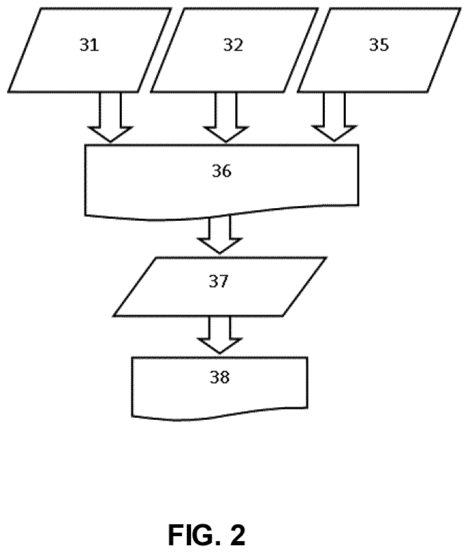

An exemplary flow chart for simulating lithography in a lithographic projection apparatus is illustrated in FIG. 2. A source model 31 represents optical characteristics (including radiation intensity distribution, bandwidth and/or phase distribution) of the source. A projection optics model 32 represents optical characteristics (including changes to the radiation intensity distribution and/or the phase distribution caused by the projection optics) of the projection optics. A design layout model 35 represents optical characteristics (including changes to the radiation intensity distribution and/or the phase distribution caused by a given design layout 33) of a design layout, which is the representation of an arrangement of features on or formed by a patterning device. An aerial image 36 can be simulated from the design layout model 35, the projection optics model 32 and the design layout model 35. A resist image 38 can be simulated from the aerial image 36 using a resist model 37. Simulation of lithography can, for example, predict contours and CDs in the resist image.

More specifically, it is noted that the source model 31 can represent the optical characteristics of the source that include, but not limited to, numerical aperture settings, illumination sigma (σ) settings as well as any particular illumination shape (e.g., off-axis radiation sources such as annular, quadrupole, dipole, etc.). The projection optics model 32 can represent the optical characteristics of the projection optics, including aberration, distortion, one or more refractive indexes, one or more physical sizes, one or more physical dimensions, etc. The design layout model 35 can represent one or more physical properties of a physical patterning device, as described, for example, in U.S. Pat. No. 7,587,704, which is incorporated by reference in its entirety. The objective of the simulation is to accurately predict, for example, edge placement, aerial image intensity slope and/or CD, which can then be compared against an intended design. The intended design is generally defined as a pre-OPC design layout which can be provided in a standardized digital file format such as GDSII or OASIS or another file format.

From this design layout, one or more portions may be identified, which are referred to as “clips”. In an embodiment, a set of clips is extracted, which represents the complicated patterns in the design layout (typically about 50 to 1000 clips, although any number of clips may be used). These patterns or clips represent small portions (e.g., circuits, cells or patterns) of the design and more specifically, the clips typically represent small portions for which particular attention and/or verification is needed. In other words, clips may be the portions of the design layout, or may be similar or have a similar behavior of portions of the design layout, where one or more critical features are identified either by experience (including clips provided by a customer), by trial and error, or by running a full-chip simulation. Clips may contain one or more test patterns or gauge patterns.

An initial larger set of clips may be provided a priori by a customer based on one or more known critical feature areas in a design layout which require particular image optimization. Alternatively, in another embodiment, an initial larger set of clips may be extracted from the entire design layout by using some kind of automated (such as machine vision) or manual algorithm that identifies the one or more critical feature areas.

In an embodiment, the design layout or portions of the design layout are used for designing a mask to be employed in the semiconductor manufacturing. A mask design includes determining mask features based on mask optimization simulations and checking whether mask rule checks (MRC) are satisfied. In an embodiment, the mask design includes Manhattan shaped mask feature or curvilinear mask features. The mask features are desired to satisfy mask rule checks associated with mask manufacturing process. As the mask design technology e.g., optical proximity correction (OPC) technology is migrating from Manhattan to curvilinear shapes, current MRC engine can no longer consistently flag MRC violations and drive optimization. In an embodiment, the MRC includes one or more constrains related to geometric properties associated with the mask feature that can be manufactured. For example, the geometric properties include, but not limited, to a minimum CD of a mask feature, a minimum curvature of mask feature that can be manufactured, or a minimum space between two features that can be manufactured.

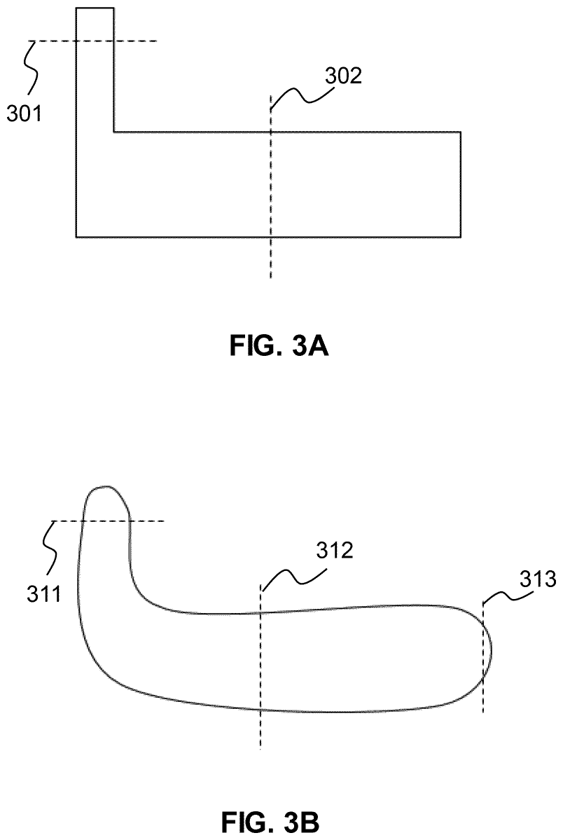

FIG. 3A illustrates typical MRC performed on a Manhattan feature, and FIG. 3B illustrates typical MRC performed on a curvilinear feature. For example, in the current MRC engine a cutline is drawn across the feature shape and a distance between points intersecting the mask feature is measured for MRC. As shown in FIG. 3A, a horizontal cutline 301 and a vertical cutline 302 cuts across the Manhattan shaped mask feature. The distance between the points where the cutline 301 (or the cutline 302) intersect the mask feature is used to check whether the mask feature satisfies the MRC. However, when the cutlines are used for determining MRC violations for curvilinear mask feature, several false violations may be detected. As shown in FIG. 3B, cutlines 311, 312 and 313 may be used to determine MRC violations of the mask feature. It can be seen that as the cutline gets closer to a tip of the feature, MRC violations are highly likely to be detected because the tip has a relatively narrower width compared to other portions of the mask feature. For example, the cutline 313 will flag the location of the mask feature as violating the MRC. However, such curved tip can be easily manufactured via a mask manufacturing apparatus. Hence, the violation detected by the cutline 313 is false. Typically, a mask may have thousands or even millions of mask features for which MRC may be performed. If high number of MRC violations are falsely detected, then an amount of computational resources and time, manual effort and time and even manufacturing time will be substantially high. As such, an improved detector is required for curvilinear shaped mask feature so that such false violation detections are minimum to none.

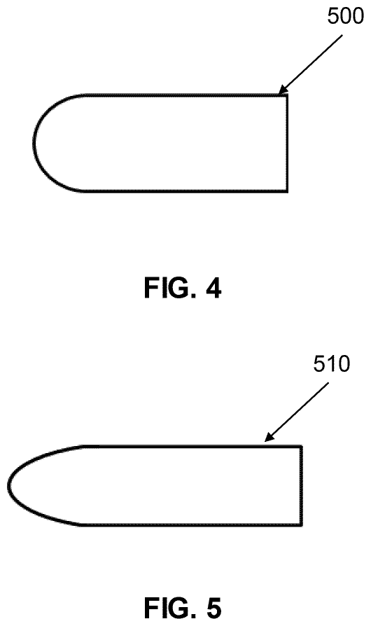

FIGS. 4 and 5 illustrate mask features 500 and 510 having a rounded tip and a narrower tip, respectively. A detector that can be used with both rounded tips and narrower tips may be desired to avoid false violation detection. In the present examples, tips are used to explain the limitations of the existing MRC technology. In some embodiments, sharp curved features may be encountered anywhere along a length of the feature and not limited to tips.

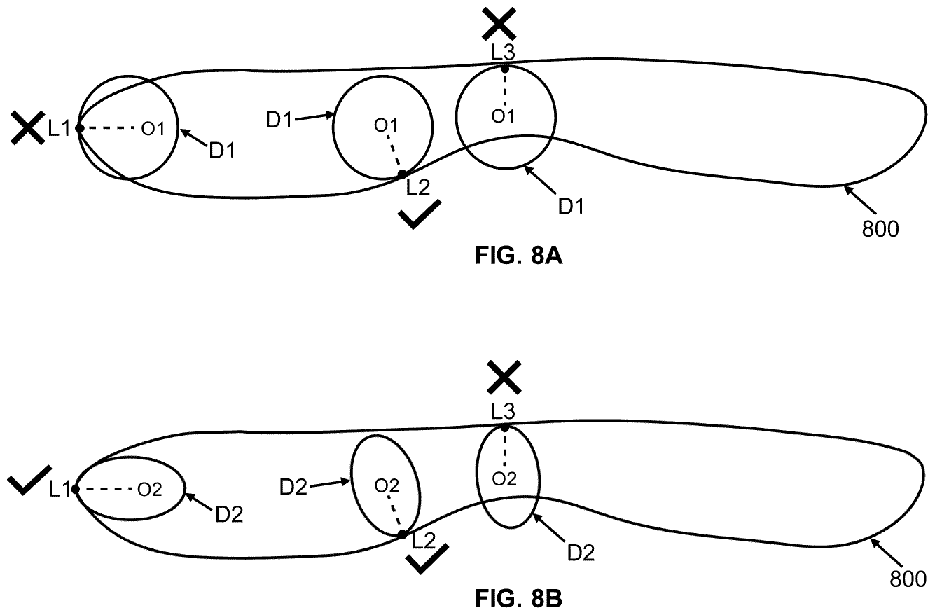

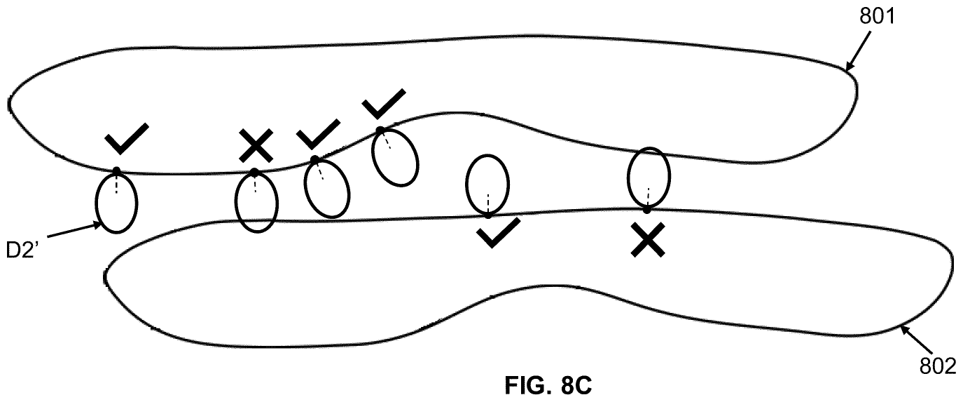

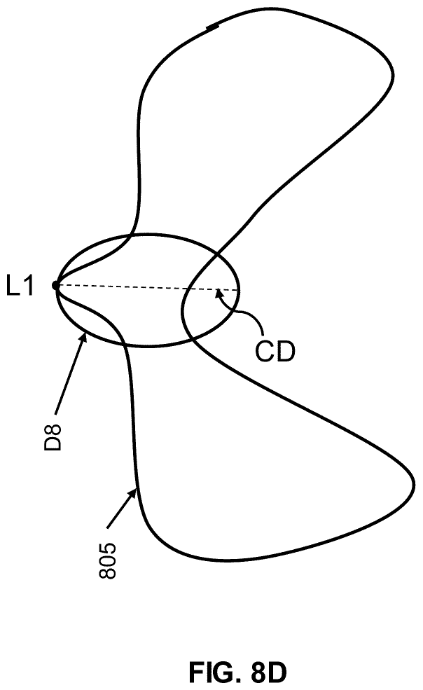

The MRC detector needs to be flexible enough to accommodate different mask manufacturing technologies, especially in curvilinear feature shapes having sharper curves such as tips. The tip shapes of the mask feature may depend on mask manufacturing technology as well as may differ through use cases (e.g., chip designs) and machine settings. The present disclosure provides a detector that can be configured to perform MRC for curvilinear masks having different curvature shapes and sizes. In some examples, the detector can be configured to detect MRC violations related to spaces between two mask features (e.g., see FIG. 8C). The detectors of the present disclosure provide several advantages including, but not limited to, substantially less number of false MRC violations compared to existing cutline-based checks, provides a user defined detector that the user can define based on its own manufacturing limitations, the detector can be employed to improve mask designs, or improve other aspects related to semiconductor manufacturing processes.

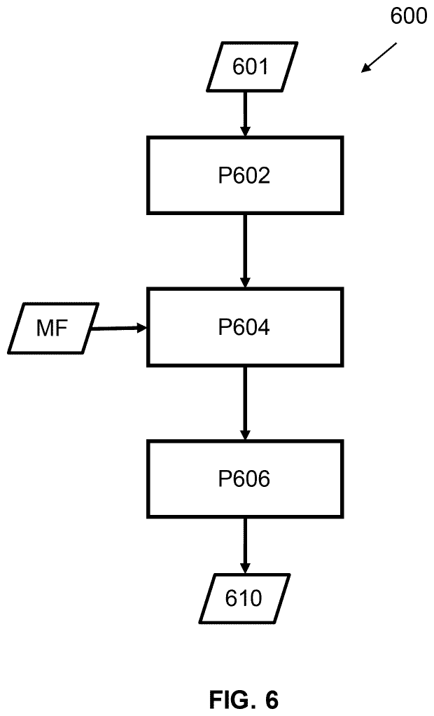

FIG. 6 is a flowchart of an exemplary method for determining mask features that violate MRC, according to an embodiment of the present disclosure. In an embodiment, MRC violation is determined based on a detector having a particular shape and an orientation axis for guiding the relative positioning of the detector with the mask feature. The detector is slide along the edge of the mask feature. The detector has an enclosed or substantially enclosed shape, and an MRC violation is detected when a portion of the mask feature is inside the enclosed shape.

Process P602 involves obtaining a detector 601 having geometric properties configured to facilitate MRC detection, and a mask feature MF. In an embodiment, the detector 601 is configured to include a curved portion to detect a curvature violation, an enclosed area, an orientation axis configured to guide relative positioning of the detector 601 with the mask feature MF, and a length along the orientation axis to detect a critical dimension violation or a space violation. In an embodiment, a plurality of detectors having different shapes and sizes may be employed for a mask feature or multiple mask features. In an embodiment, the mask feature MF has a curvilinear shape. In an embodiment, the MRC may include one or more geometric properties associated with the mask feature MF. The geometric properties include, but not limited, a minimum CD of a mask feature that can be manufactured, a minimum curvature of mask feature that can be manufactured, or a minimum space between two features that can be manufactured.

In an embodiment, the obtaining of the detector 601 involves accessing a detector from a library of detectors. In an embodiment, obtaining involves receiving a pre-defined detector defined based on a shape and size of the mask feature MF and mask feature manufacturing limitations associated with a mask manufacturing process. For example, a user may define a curvature, a length, a width, an area, or geometry of the detector. Furthermore, the user may define an orientation axis of the detector 601, for example, the orientation axis may indicate a direction along a perpendicular a point of the curved portion of the detector 601.

In an embodiment, the detector 601 may be non-circular, for example, and may have an oval, a key shape, or an irregular curved shape having different radius of curvatures. For example, the detector 601 has a first curved portion and a second curved portion different from the first curved portion. The first curved portion has a first radius of curvature, and the second curved portion has a second radius of curvature, where the first radius is different from the second radius. In an embodiment, the detector 601 may be drawn using a drawing tool configured to allow a user to define shapes of different radius of curvatures and orientation axis. In an embodiment, the detector 601 may be represented as a polynomial equation, pixel representation, a GDSII or OASIS compatible representation, or other digital file formats.

In an embodiment, obtaining of the detector 601 involves receiving the detector 601 shaped based on feature size, and a curvature of the mask feature MF that is dictated by mask manufacturability or other limits. For example, a user may define the curved portion of the detector 601 to have a shape and size corresponding to a curvature of a tip portion of the mask feature MF, and a minimum size of the mask feature MF that can be manufactured.

In an embodiment, obtaining of the detector 601 involves receiving (e.g., via a user interface or a database) a single detector configured to determine MRC violations including a curvature violation and a width violation associated with the mask feature MF. In an embodiment, obtaining of the detector 601 involves receiving (e.g., via a user interface or a database) a single detector configured to determine MRC violations associated with a curvature violation and a space violation between at least two mask features.

In an embodiment, the obtaining of the detector 601 includes accessing, from a library of detectors, the detector 601 for determining MRC violation of the mask feature MF. In an embodiment, the library of detectors includes a plurality of detectors, each detector having a different shape and size than other detectors defined.

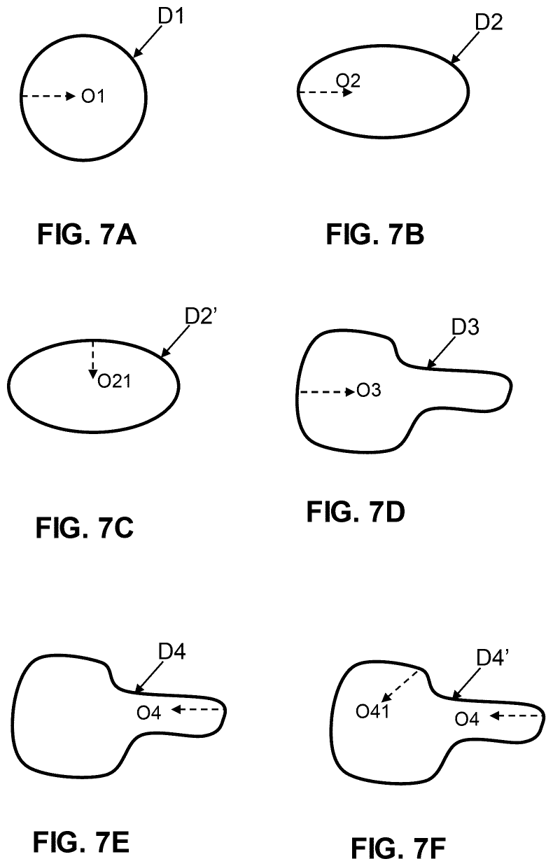

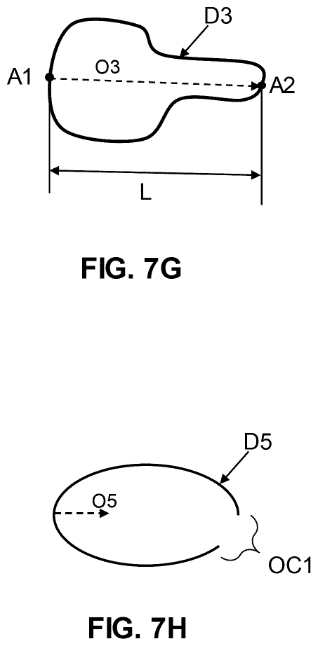

FIGS. 7A-7F illustrate detectors D1, D2, D2′, D3, D4, and D4′ of different shape and sizes, according to an embodiment of the present disclosure. Each detector has a particular shape and a particular orientation axis that may be defined based on the mask feature size, limitations related to curvature of the mask features, or other geometric properties related to the mask features. In FIG. 7A, the detector D1 has a circular shape and an orientation access O1. In an embodiment, the orientation axis O1 may be defined from any other point on the circumference of the circle in a desired direction defined by the user.

In FIG. 7B, the detector D2 has an elliptical shape and an orientation axis O2. In another example, in FIG. 7C, the detector D2′ also has the elliptical shape similar to D2, but an orientation axis O21 is different from the orientation axis O2. As such, the detector D2′ is different from the detector D2. In other words, MRC violations detected by D2 may be different from that detected by D2′. In an embodiment, the curvature of elliptical shape may be defined based on a curvature of the tip of the mask feature that can be manufactured. The detector D2 has a first curved portion and a first orientation axis O2, which may be drawn perpendicular to a point of the first curved portion. The detector D2 also has a second curved portion and a second orientation axis O21, which is drawn perpendicular to a point on the second curved portion. As can be seen, the first curved portion is relatively sharper than the second curved portion. In other words, the first curved portion has a smaller radius of curvature compared to the second curved portion.

In FIGS. 7D-7G, the detectors D3, D4 and D4′ have an irregular shape with multiple curved portions of different radius of curvatures and an orientation axis such as O3 defined perpendicular to a curved portion of the irregular shape. The detector D4 has an irregular shape similar to the detector D3 however a different orientation axis O4 may be defined at a different location than that in the detector D3. In one embodiment, the detector D4′ may have different orientation axis O4 and O41 define at different locations update regular ship. Each of the orientation axis O4 and O41 may also be perpendicular to corresponding point on a curved portion of the detector D4′. Thus, a similar shaped detector may be used differently based on the orientation axis. For example, the detector D3 having the orientation axis O3 may be used for detecting MRC violations of a wide tip, and the detector D4 having the orientation axis O4 may be used for detecting MRC violations of a narrow tip.

In FIG. 7G, the detector D3 may be further characterized by the length L. In an embodiment, the length L may correspond to a critical dimension of the mask feature. In an embodiment, the length L may be defined as a distance between points of intersection of the orientation axis with the boundary or edge of the detector D3, or the length of D3 along the orientation axis. For example, the orientation axis O3 may be drawn from point A1 and further extended to intersect with the edge at point A2. Accordingly, the length of the detector D3 may be adjusted by moving the point A2 toward A1 to decrease the length L or away from A1 to increase the length L. Thus, in an embodiment, the single detector D3 may be used to determine MRC violation at a curvature of a mask feature, as well as CD violation along at different locations along the length of the mask feature. Similarly, a size (e.g., a length or width) of the detectors D1, D2, D2′, D3, D4, and D4′ may be defined.

The present disclosure is not limited to shape and sizes discussed herein. Also, although the exemplary detectors (e.g., in FIGS. 7A-7G) have an entirely closed shape, the present disclosure is not limited to such enclosed shapes. A person of ordinary skill in the art may define an open shape detector. For example, a small opening may be provided in the detector shape away from the orientation axis that would not interfere with the function of detecting either space or curvature violations. For example, even with a small opening, portions of the mask feature may intersect with detector thereby detecting a curvature, size violation, or both. For example, FIG. 7H illustrates a detector D5 having an orientation axis O5 and a small opening OC1. The opening OC1 is located away from the orientation axis O5, thus does not affect a curvature violation detection capability of the detector D5. Additionally, the opening OC1 is not along the length of the orientation axis O5, thus the opening will not interfere with size detection capability of the detector D5.

Process P604 involves aligning the orientation axis with a normal axis at a location on the mask feature MF. The normal axis is a normal drawn perpendicular to a curve at the location of interest of the mask feature MF. In an embodiment, aligning the orientation axis of the detector 601 with the normal axis of the mask feature MF involves determining a normal axis at the location of the mask feature MF; contacting an edge of the detector 601 with an edge of the feature at the location; and aligning or orienting the orientation axis of the detector 601 with the normal axis at the location of the feature. Such aligning of the detector 610 and the mask feature MF enables MRC violations caused due to curvatures as well as size to be detected. Thus, during the MRC detection along the mask feature MF, the detector 610 may be oriented and re-oriented several times depending on the geometry of the mask feature. An advantage of such orientation and re-orientation is providing the flexibility of using a single detector to check multiple MRC constraints (e.g., curvature and size) simultaneously. Example orientation and re-orientation of the detector 610 is illustrated in FIG. 8B for visual understanding of the aligning of detector and identifying MRC violations.

Although embodiments of the present disclosure are described in detail with an orientation axis of a detector aligned with a normal axis at each location of the mask feature, the present disclosure is not limited thereto. In some embodiments, during detection, a detector may be slid along the mask feature edge with its orientation axis maintaining a certain non-zero angle with the normal axis at each location of the mask feature. In this manner, the length of the detector extends along a prescribed axis of the location on the mask feature, where the prescribed axis forms the certain non-zero angle with the normal axis of the mask feature location.

Process P606 involves identifying, based on the detector 601 aligned with the mask feature MF, an MRC violation 610 corresponding to a region of the mask feature MF that intersects the enclosed area. In an embodiment, identifying the MRC violation 610 includes determining the MRC violations by sliding the detector 610 along an edge of the mask feature MF while maintaining the orientation axis of the detector 610 aligned to a normal axis of each location of the mask feature MF.

In an embodiment, identifying the MRC violation 610 involves (a) aligning the orientation axis of the detector 610 with a first normal axis at a first location of the mask feature MF; (b) identifying, based on the detector aligned with the mask feature MF, whether a region of the mask feature MF around the first location is inside the enclosed area; (c) responsive to the region of the mask feature MF being inside the enclosed area, flagging the first location as the MRC location; and (d) responsive to the region of the mask feature MF not being inside the enclosed area, sliding the detector to a second location of the mask feature MF, and identifying the MRC violation 610 by performing steps (a)-(c) at the second location, for example, using a second normal axis at the second location of the mask feature MF.

FIG. 8A illustrates identifying of MRC violations associated with a mask feature by employing a circular detector, according to an embodiment of the present disclosure. In the example shown, a mask feature 800 has a curvilinear shape with end portions (e.g., tips) having smaller size than remaining portions of the feature 800. It can be seen that along the length of the mask feature 800, the size (e.g., CDs measured along a vertical direction at different locations) varies substantially. As such, one or more MRC violations may occur for the mask feature 800. According to some embodiments, such MRC violations are determined using a detector having different shapes and sizes, which are defined based on the geometry of the mask feature.

In FIG. 8A, a circular detector D1 having a diameter corresponding to a desired CD value (e.g., an MRC rule) of the mask feature may be defined. The detector D1 also has an orientation axis O1 (e.g., dotted line inside the circle). In an embodiment, MRC violations may be determined by sliding the detector D1 inside the mask feature along the length of the mask feature. In an embodiment, an MRC violation is detected when a portion of the mask feature is inside the detector D1. In an embodiment, an absence or occurrence of an MRC violation at a first location L1 is determined by aligning the orientation axis O1 (dotted line) with a normal axis (not shown) of the mask feature at the first location L1. At the first location L1, the detector D1 includes a portion of the mask feature inside the enclosed area. Hence, the first location L1 may be flagged as an MRC violation. In an embodiment, geometric properties associated with the mask feature may be extracted and further used for performing mask designs (e.g., OPC). For example, upon detecting an MRC violation, geometric properties such as a curvature, length of the feature inside the detector, etc. may be determined.

Similarly, at a second location L2, the orientation axis O1 of the detector D1 may be aligned with a normal axis at the second location L2. It can be seen that the detector D1 does not includes any portion of the mask feature inside the enclosed area. Hence, the second location L2 may not be flagged as an MRC violation, or may be flagged as satisfying the MRC. Similarly, at a third location L3, an MRC violation may be detected and geometric properties of the mask feature at location L3 may be extracted similar to at location L1.

A circular detector may be limited to either a size violation detection or a curvature detection, but not both. In other words, multiple circular detectors may be needed to detect different types of MRC violation. On the other hand, the detector according to the present disclosure are configured to determine, using a single detector, different types of violations. As such, a single pass along the mask feature may determine different types of violations. Examples of detectors in present disclosure are shown in FIGS. 7B-7G, and example detection process using an elliptical detector is illustrated in FIGS. 8B and 8C.

FIG. 8B illustrates identifying of MRC violations associated with the mask feature 800 by a non-circular detector, according to an embodiment of the present disclosure. The detector D2 has at least two curved portions, a first curved portion being narrower than a second curved portion. The curved portions may be user defined based on limitations of mask features that can be manufactured. For example, the first curved portion may correspond to a minimum curvature that can be manufactured. In this example, the non-circular detector D2 has an elliptical shape. A length (e.g., along a major axis of the ellipse) of the detector D2 may correspond to a CD threshold to be flagged as MRC violation. In an embodiment, the orientation axis O2 may be defined perpendicular to the first curved portion and used to guide the orientation of the detector D2 with respect to the mask feature 800 at any given point of the mask feature.

In an embodiment, MRC violations may be determined by sliding the detector D2 inside the mask feature along the edge of mask feature and orienting the detector D2 based on the orientation axis O2. In an embodiment, an MRC violation is detected when a portion of the mask feature is inside the detector D2. In an embodiment, an absence or occurrence of an MRC violation at a first location L1 is determined by aligning the orientation axis O2 (dotted line) with a normal axis (not shown) of the mask feature at the first location L1.

At the first location L1, the detector D2 does not include any portion of the mask feature inside the enclosed area, or does not intersects with the mask feature edge except the point or points of tangency around L1. Hence, the first location L1 is not flagged as an MRC violation. Similarly, at a second location L2, the orientation axis O2 of the detector D2 may be aligned with a second normal axis at the second location L2. It can be seen that the detector D1 does not includes any portion of the mask feature inside the enclosed area. Hence, the second location L2 is not flagged as an MRC violation, or may be flagged as satisfying the MRC. At a third location L3, the detector D2 is oriented by aligning the orientation axis O2 with a third normal axis at the location L3 as D2 intersects with the mask edge in addition to points of tangency. Upon orientating, an MRC violation may be detected, as a portion of the mask feature 800 is inside the detector D2. For example, at location L3, a CD violation is detected by the detector D2 because a length of the detector (which characterizes CD violations) along the orientation axis causes a portion of the mask feature 800 to intersect with the detector D2 and cause the portion of the mask feature 800 to be inside the detector D2. In an embodiment, at location L3, geometric properties of the mask feature at location L3 may be extracted similar to at location L1. In an embodiment, geometric properties associated with the mask feature may be extracted and further used for performing mask designs (e.g., OPC). For example, upon detecting an MRC violation, geometric properties such as a curvature, length of the feature inside the detector, etc. may be determined.

FIG. 8C illustrates identifying of MRC violations associated with two adjacent mask features 801 and 802 by a non-circular detector, according to an embodiment of the present disclosure. In this example, a detector D2′ is configured to have a length along an orientation axis equal to a minimum space between two features, and a curvature portion, at which the orientation axis is drawn, has a radius of curvature equal to a minimum curvature that can be manufactured. To detect MRC violations between two features 801 and 802, the detector is slid between edges of the two features 801 and 802 along an edge of the feature 801 and/or along an edge of the feature 802. As shown, the detector D2′ detects at least two space violations, as indicated by the cross signs. A first space violation is detected when sliding the detector D2′ along the edge of the feature 801, and a second space violation is detected when sliding the detector D2′ along the edge of the feature 802. Thus, the orientation and size of the detector D2′ allow detection of space violations for different curved portions of the mask feature.

FIG. 8D illustrates an example of both curvature violation and size (e.g., CD) violation detected at a single location L1 on a mask feature 805 by a single detector. At the location L1, when a detector D8 is oriented based on the orientation axis (dotted line) to align with a normal to a curvature of the mask feature 805 at location L1, a portion of the curvature intersects the detector D8. Also, along the length CD of the detector D8, another portion of the mask feature 805 intersects the detector D8. A first portion at location L1 that falls within the boundary of the detector D8 indicates a curvature violation detected, and a second portion at the other end of the location L1 that falls within the boundary of the detector D8 indicates a size CD of the mask feature 805 at location L1 is violated. Thus, the detector D8 advantageously indicates both curvature and CD violation at a single location L1.

The above examples show different types of MRC violations (e.g., CD violation, curvature violation) at different locations on mask features. Depending on the shape of the mask features, the detector may detect only CD violation, only curvature violation, or both CD and curvature violation at a single position. Thus, the detectors configured according to the present disclosure can advantageously detect multiple types of violation at a single position of a mask feature using a single detector thereby enhancing MRC violation detecting capabilities in a single pass over the mask feature. Accordingly, modifications may be made to the mask feature shapes to overcome such multiple violations in a single step, which in turn will reduce the number of iterations that may be required in a mask design process and expedite the mask design process.

In an embodiment, the method 600 further involves performing a mask design by employing the detectors discussed herein. In an embodiment, the mask design process may determine shape and size of mask features of the mask design using MRC violations detected by one or more detectors discussed herein. As an example, performing of the mask design involves (a) simulating, using a design layout, a mask optimization process to determine the mask features for the mask design, the design layout corresponding to features to be printed on a semiconductor chip; (b) determining, via the detector, portions of the mask features that violate the MRC (e.g., as discussed with respect to processes P602-606); and (c) responsive to violating the MRC, modifying the corresponding portions of the mask features to satisfy the MRC; and repeating steps (a)-(c).

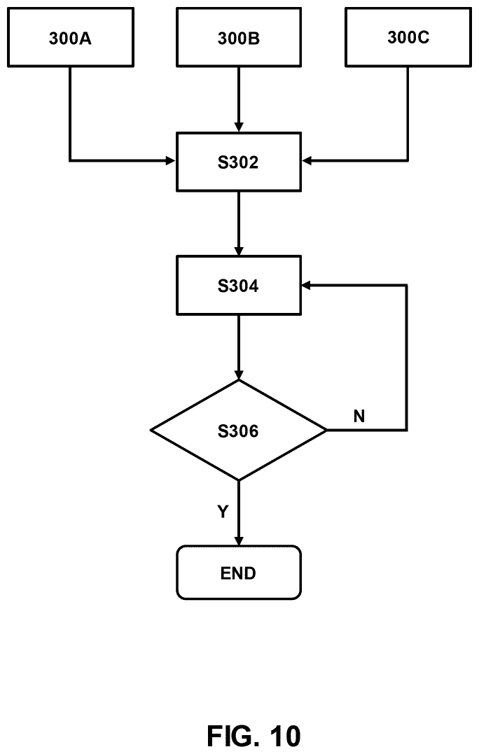

In an embodiment, the mask optimization process involves a mask only optimization process, a source mask co-optimization process, and/or an optical proximity correction process. Example mask design process including OPC are discussed with respect to FIGS. 10-13. In an embodiment, the OPC process may be adapted to include MRC check as discussed herein.

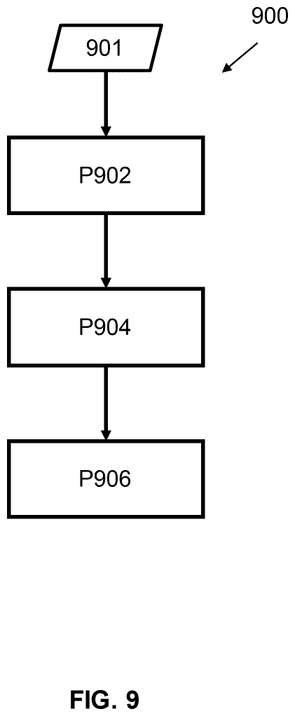

In an embodiment, the OPC process may be tailored to include the MRC violation check using detectors as discussed herein (e.g., FIGS. 7A-7G and 8A-8D), where the detectors may be defined according to mask manufacturing limitations. In an embodiment, one or more detectors may be used to identify mask features or portions of mask features that are within the detector. In an embodiment, the portions of the mask features being within the detector may be modified to satisfy the MRC. In an embodiment, the check may be performed at after particular number of iterations, at an end of the OPC process, at fixed number of iterations, or other points in the simulation. After modifying the mask features that violate the MRC, the OPC may be repeated to ensure cost functions associated with the OPC remain valid or within desired limits. In this way, the mask features obtained after the OPC simulation process will not only satisfy MRC, but also design specifications associated with the cost function. An example of mask design process is further discussed in detail with respect to FIG. 9.

FIG. 9 is a flowchart of a method 900 for determining a mask design based on detectors (e.g., of FIGS. 7A-7G), according to an embodiment of the present disclosure. In an embodiment, the method of mask design includes determining MRC violations e.g., as discussed above. Based on the MRC violation information associated with the portions of the mask features, geometric properties of the mask features may be modified. An exemplary method 900 is discussed with respect to processes P902, P904, and 906.

Process P902 involves simulating a mask optimization process using a design layout to determine mask features for the mask design. The design layout includes features corresponding to target features to be printed on a semiconductor chip. In an embodiment, the mask optimization process involves executing one or more process models of a patterning process and performing mask design to determine curvilinear shapes of the mask feature. The process model may be a rigorous, empirical or semi-empirical physical model or a machine learning model. In an embodiment, the mask design involves free form mask design, level-set method, or other methods related to continuous transmission mask (CTM), etc. However, although such curvilinear may generate ideal target features to be printed on the semiconductor chip, it is desired to perform MRC violations related to the mask features to ensure manufacturability of the mask to be employed in the patterning process.

Process P904 involves determining MRC violations by a detector 901. In an embodiment, the determination of MRC violations involves determining portions of the mask features that violate a mask rule check (MRC). As discussed herein, an example detector has a curved portion, an enclosed area, and an orientation axis that is perpendicular to a point of the curved portion (e.g., as discussed with respect to FIGS. 7A-7G). In an embodiment, the orientation axis extends inside or outside the enclosed area of the detector 901.

In an embodiment, the MRC includes one or more geometric properties associated with the mask feature. For example, the geometric properties include at least one of: a minimum CD of a mask feature that can be manufactured, a minimum curvature of mask feature that can be manufactured, or a minimum space between two features that can be manufactured.

In an embodiment, the determining the portions of the mask features that violate the MRC involves obtaining the detector 901 having geometric properties corresponding to the MRC; aligning the orientation axis with a normal direction of a location on a mask feature; and identifying the MRC violation corresponding to a region of the mask feature that intersects the enclosed area based on the aligned detector and the mask feature.

In an embodiment, the detector 901 is a non-circular. A non-circular detector may be characterized by a shape having a plurality of radius of curvatures. For example, the non-circular detector includes a first curved portion having a first radius of curvature and a second curved portion having a second radius of curvature. The first radius is different from the second radius. In an embodiment, the detector 901 is shaped based on feature size, and a curvature of the mask feature that can be manufactured. As an example, the curved portions of the detector 901 has a shape and size corresponding to a curvature of a tip portion of the mask feature, and a minimum size of the mask feature that can be manufactured.

In an embodiment, obtaining the detector 901 involves receiving (e.g., via a user interface or a database) a single detector configured to determine MRC violations including a curvature violation and a width violation associated with the mask feature. In an embodiment, obtaining the detector 901 comprises receiving (e.g., via a user interface or a database) a single detector configured to determine MRC violations associated with a curvature violation and a space violation between at least two mask features.

In an embodiment, aligning the orientation axis of the detector 901 with a normal axis of the mask feature involves determining a normal axis at the location of the mask feature; contacting an edge of the detector 901 with an edge of the feature at the location; and orienting the orientation axis of the detector 901 with the normal axis at the location of the feature.

In an embodiment, identifying the MRC violation involves determining the MRC violations by sliding the detector 901 along an edge of the mask feature while maintaining the orientation axis of the detector 901 aligned to a normal axis of each location of the mask feature.

In an embodiment, identifying the MRC violation involves (a) aligning the orientation axis of the detector 901 with a first normal axis at a first location of the mask feature; (b) identifying, based on the aligned detector and the mask feature, whether a region of the mask feature around the first location is inside the enclosed area; (c) responsive to the region of the mask feature being inside the enclosed area, flagging the first location as the MRC location; and (d) responsive to the region of the mask feature not being inside the enclosed area, sliding the detector 901 to a second location of the mask feature, and identifying the MRC violation by performing steps (a)-(c) at the second location, for example, using a second normal axis at the second location of the mask feature. An example of steps of aligning, orientating, and identifying of MRC violation are illustrated in FIG. 8A-8B.

Process P906 involves responsive to the portions violating the MRC, modifying the corresponding portions of the mask features to satisfy the MRC. In an embodiment, modifying the mask features may involve increasing or decreasing a size and/or a curvature of the portions of the mask features to satisfy the MRC using the detector 901. In an embodiment, modifying the mask features is an iterative process. Each iteration may involve executing one or more process models associated with a patterning process using the modified mask features to generate target features to be printed on the semiconductor chip; determining whether the target features satisfy design specification associated with the design layout; and responsive to design specification not being satisfied, modifying the mask features to satisfy the design specification.

Examples of mask optimization process including OPC process are further discussed in detail with respect to FIGS. 10-13. These mask optimization processes can be modified as discussed with respect to the method 900 to enable mask design. In an embodiment, the mask optimization process involves computing a cost function as a function of parameters associated with the lithographic process, and a mask. For example, the mask features may be represented as design variables, as discussed herein. These design variables will be affected due to changes based on the MRC violations detected by the detectors.

According to present disclosure, the combination and sub-combinations of disclosed elements constitute separate embodiments. For example, a first combination includes obtaining a detector, and determining MRC violations associated with mask features. The sub-combination may include the detector being a particular enclosed shape and size based on the mask feature, where MRC violations occur when a portion of the mask feature is inside the detector. In another sub-combination, the detector may be circular, or a non-circular shape. In another example, the combination includes determining a mask design based on a detector identified MRC violations. The detector having a non-circular shape that detects width, space and/or curvature violations.

In a lithographic process, as an example, a cost function may be expressed as

$$\\ \begin{matrix}CF ( {z}_{1} , {z}_{2} , … , {z}_{N} ) = {\sum }_{p = 1}^{P} {w}_{p} {f}_{p}^{{}_{} 2} ( {z}_{1} , {z}_{2} , … , {z}_{N} ) & ( Eq . 1 )\end{matrix}$$

wherein (z₁, z₂, . . . , z_{N}) are N design variables or values thereof. fₚ (z₁, z₂, . . . , z_{N}) can be a function of the design variables (z₁, z₂, . . . , z_{N}) such as a difference between an actual value and an intended value of a characteristic at an evaluation point for a set of values of the design variables of (z₁, z₂, . . . , z_{N}). wₚ is a weight constant associated with fₚ (z₁, z₂, . . . , z_{N}). An evaluation point or pattern more critical than others can be assigned a higher wₚ value. Patterns and/or evaluation points with larger number of occurrences may be assigned a higher wₚ value, too. Examples of the evaluation points can be any physical point or pattern on the substrate, any point on a virtual design layout, or resist image, or aerial image, or a combination thereof. CF (z₁, z₂, . . . , z_{N}) can be a function of the illumination source, a function of a variable that is a function of the illumination source or that affects the illumination source. Of course, CF (z₁, z₂, . . . , z_{N}) is not limited to the form in Eq. 1. CF(z₁, z₂, . . . , z_{N}) can be in any other suitable form.

The cost function may represent any one or more suitable characteristics of the lithographic projection apparatus, lithographic process or the substrate, for instance, focus, CD, image shift, image distortion, image rotation, stochastic variation, throughput, local CD variation, process window, or a combination thereof. In one embodiment, the design variables (z₁, z₂, . . . , z_{N}) comprise one or more selected from dose, global bias of the patterning device, and/or shape of illumination. In one embodiment, the design variables (z₁, z₂, . . . , z_{N}) comprise the bandwidth of the source. Since it is the resist image that often dictates the pattern on a substrate, the cost function may include a function that represents one or more characteristics of the resist image. For example, fₚ (z₁, z₂, . . . , z_{N}) of such an evaluation point can be simply a distance between a point in the resist image to an intended position of that point (i.e., edge placement error EPEₚ (z₁, z₂, . . . , z_{N})). The design variables can include any adjustable parameter such as an adjustable parameter of the source (e.g., the intensity, and shape), the patterning device, the projection optics, dose, focus, etc.

The lithographic apparatus may include components collectively called a “wavefront manipulator” that can be used to adjust the shape of a wavefront and intensity distribution and/or phase shift of a radiation beam. In an embodiment, the lithographic apparatus can adjust a wavefront and intensity distribution at any location along an optical path of the lithographic projection apparatus, such as before the patterning device, near a pupil plane, near an image plane, and/or near a focal plane. The wavefront manipulator can be used to correct or compensate for certain distortions of the wavefront and intensity distribution and/or phase shift caused by, for example, the source, the patterning device, temperature variation in the lithographic projection apparatus, thermal expansion of components of the lithographic projection apparatus, etc. Adjusting the wavefront and intensity distribution and/or phase shift can change values of the evaluation points and the cost function. Such changes can be simulated from a model or actually measured.

The design variables may have constraints, which can be expressed as (z₁, z₂, . . . , z_{N})∈Z, where Z is a set of possible values of the design variables. One possible constraint on the design variables may be imposed by a desired throughput of the lithographic projection apparatus. Without such a constraint imposed by the desired throughput, the optimization may yield a set of values of the design variables that are unrealistic. For example, if the dose is a design variable, without such a constraint, the optimization may yield a dose value that makes the throughput economically impossible. However, the usefulness of constraints should not be interpreted as a necessity. For example, the throughput may be affected by the pupil fill ratio. For some illumination designs, a low pupil fill ratio may discard radiation, leading to lower throughput. Throughput may also be affected by the resist chemistry. Slower resist (e.g., a resist that requires higher amount of radiation to be properly exposed) leads to lower throughput. In an embodiment, the constraints on the design variables are such that the design variables cannot have values that change any geometrical characteristics of the patterning device-namely, the patterns on the patterning device will remain unchanged during the optimization.

The optimization process therefore is to find a set of values of the one or more design variables, under the constraints (z₁, z₂, . . . , z_{N})∈Z, that optimize the cost function, e.g., to find:

$$\\ \begin{matrix}( {\tilde{z}}_{1} , {\tilde{z}}_{2} , … , {\tilde{z}}_{N} ) = arg {min}_{( {z}_{1} , {z}_{2} , … , {z}_{N} ) ∈ Z} CF ( {z}_{1} , {z}_{2} , … , {z}_{N} ) & ( Eq . 2 )\end{matrix}$$

A general method of optimizing, according to an embodiment, is illustrated in FIG. 10. This method comprises a step S302 of defining a multi-variable cost function of a plurality of design variables. The design variables may comprise any suitable combination selected from design variables representing one or more characteristics of the illumination (300A) (e.g., pupil fill ratio, namely percentage of radiation of the illumination that passes through a pupil or aperture), one or more characteristics of the projection optics (300B) and/or one or more characteristics of the design layout (300C). For example, the design variables may include design variables representing one or more characteristics of the illumination (300A) (e.g., being or including the bandwidth) and of the design layout (300C) (e.g., global bias) but not of one or more characteristics of the projection optics (300B), which leads to an illumination-patterning device (e.g., mask) optimization (“source-mask optimization” or SMO). Or, the design variables may include design variables representing one or more characteristics of the illumination (300A) (optionally polarization), of the projection optics (300B) and of the design layout (300C), which leads to an illumination-patterning device (e.g., mask)-projection system (e.g., lens) optimization (“source-mask-lens optimization” or SMLO). Or the design variables may include design variables representing one or more characteristics of the illumination (300A) (e.g., being or including the bandwidth), one or more non-geometrical characteristics of the patterning device, or one or more characteristics of the projection optics (300B), but not any geometrical characteristics of the patterning device. In step S304, the design variables are simultaneously adjusted so that the cost function is moved towards convergence. In an embodiment, not all design variables may be simultaneously adjusted. Each design variable may also be adjusted individually. In step S306, it is determined whether a predefined termination condition is satisfied. The predetermined termination condition may include various possibilities, e.g., one or more selected from: the cost function is minimized or maximized, as required by the numerical technique used, the value of the cost function is equal to a threshold value or crosses the threshold value, the value of the cost function reaches within a preset error limit, and/or a preset number of iterations is reached. If a condition in step S306 is satisfied, the method ends. If the one or more conditions in step S306 is not satisfied, the steps S304 and S306 are iteratively repeated until a desired result is obtained. The optimization does not necessarily lead to a single set of values for the one or more design variables because there may be a physical restraint, caused by a factor such as pupil fill factor, resist chemistry, throughput, etc. The optimization may provide multiple sets of values for the one or more design variables and associated performance characteristics (e.g., the throughput) and allows a user of the lithographic apparatus to pick one or more sets.

Different subsets of the design variables (e.g., one subset including characteristics of the illumination, one subset including characteristics of patterning device and one subset including characteristics of projection optics) can be optimized alternatively (referred to as Alternative Optimization) or optimized simultaneously (referred to as Simultaneous Optimization). So, two subsets of design variables being optimized “simultaneously” or “jointly” means that the design variables of the two subsets are allowed to change at the same time. Two subsets of design variables being optimized “alternatively” as used herein means that the design variables of the first subset but not the second subset are allowed to change in the first optimization and then the design variables of the second subset but not the first subset are allowed to change in the second optimization.

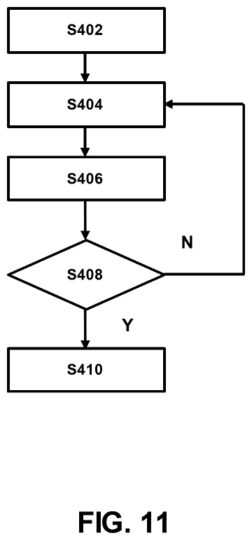

In FIG. 10, the optimization of all the design variables is executed simultaneously. Such a flow may be called simultaneous flow or co-optimization flow. Alternatively, the optimization of all the design variables is executed alternatively, as illustrated in FIG. 11. In this flow, in each step, some design variables are fixed while other design variables are optimized to optimize the cost function; then in the next step, a different set of variables are fixed while the others are optimized to minimize or maximize the cost function. These steps are executed alternatively until convergence or a certain terminating condition is met. As shown in the non-limiting example flowchart of FIG. 11, first, a design layout (step S402) is obtained, then a step of illumination optimization is executed in step S404, where the one or more design variables (e.g., the bandwidth) of the illumination are optimized (SO) to minimize or maximize the cost function while other design variables are fixed. Then in the next step S406, a projection optics optimization (LO) is performed, where the design variables of the projection optics are optimized to minimize or maximize the cost function while other design variables are fixed. These two steps are executed alternatively, until a certain terminating condition is met in step S408. One or more various termination conditions can be used, such as the value of the cost function becomes equal to a threshold value, the value of the cost function crosses the threshold value, the value of the cost function reaches within a preset error limit, a preset number of iterations is reached, etc. Note that SO-LO-Alternative-Optimization is used as an example for the alternative flow. As another example, a first illumination-patterning device co-optimization (SMO) or illumination-patterning device-projection optics co-optimization (SMLO) can be performed without allowing the bandwidth to change, followed by a second SO or illumination-projection optics co-optimization (SLO) allowing the bandwidth to change. Finally, the output of the optimization result is obtained in step S410, and the process stops.

The pattern selection algorithm, as discussed before, may be integrated with the simultaneous or alternative optimization. For example, when an alternative optimization is adopted, first a full-chip SO can be performed, one or more ‘hot spots’ and/or ‘warm spots’ are identified, then a LO is performed. In view of the present disclosure numerous permutations and combinations of sub-optimizations are possible in order to achieve the desired optimization results.

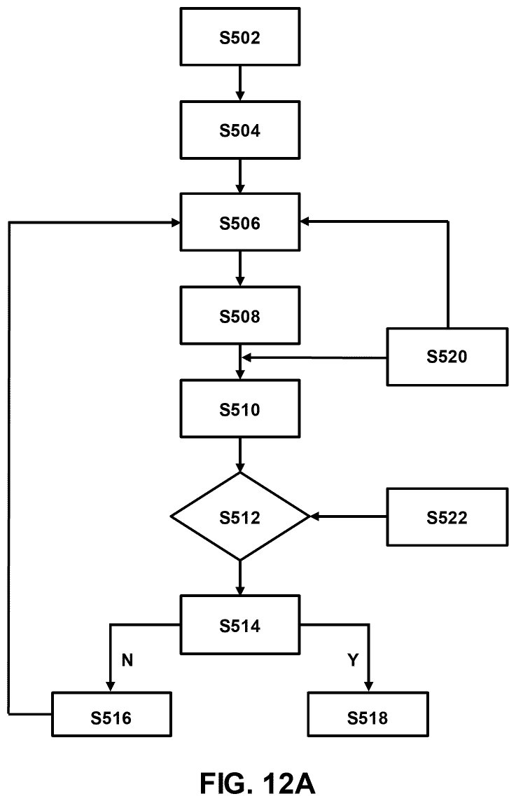

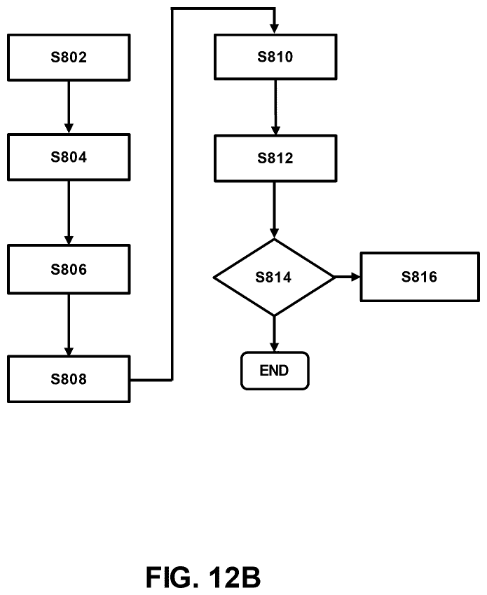

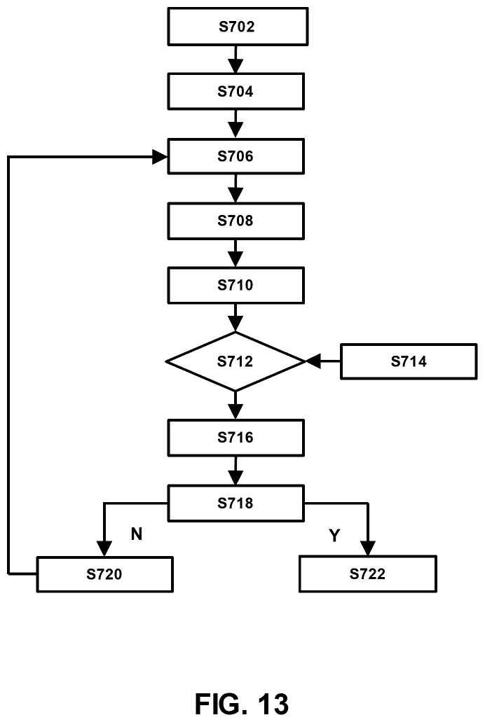

FIG. 12A shows one exemplary method of optimization, where a cost function is minimized or maximized. In step S502, initial values of one or more design variables are obtained, including one or more associated tuning ranges, if any. In step S504, the multi-variable cost function is set up. In step S506, the cost function is expanded within a small enough neighborhood around the starting point value of the one or more design variables for the first iterative step (i=0). In step S508, standard multi-variable optimization techniques are applied to the cost function. Note that the optimization problem can apply constraints, such as the one or more tuning ranges, during the optimization process in S508 or at a later stage in the optimization process. Step S520 indicates that each iteration is done for the one or more given test patterns (also known as “gauges”) for the identified evaluation points that have been selected to optimize the lithographic process. In step S510, a lithographic response is predicted. In step S512, the result of step S510 is compared with a desired or ideal lithographic response value obtained in step S522. If the termination condition is satisfied in step S514, i.e., the optimization generates a lithographic response value sufficiently close to the desired value, then the final value of the design variables is outputted in step S518. The output step may also include outputting one or more other functions using the final values of the design variables, such as outputting a wavefront aberration-adjusted map at the pupil plane (or other planes), an optimized illumination map, and/or optimized design layout etc. If the termination condition is not satisfied, then in step S516, the values of the one or more design variables is updated with the result of the i-th iteration, and the process goes back to step S506. The process of FIG. 12A is elaborated in detail below.

In an exemplary optimization process, no relationship between the design variables (z₁, z₂, . . . , z_{N}) and fₚ (z₁, z₂, . . . , z_{N}) is assumed or approximated, except that fₚ (z₁, z₂, . . . , z_{N}) is sufficiently smooth (e.g. first order derivatives

$$\\ \frac{\partial {f}_{p} ( {z}_{1} , {z}_{2} , … , {z}_{N} )}{\partial {z}_{n}} ,$$

(n=1, 2, . . . N) exist), which is generally valid in a lithographic projection apparatus. An algorithm, such as the Gauss-Newton algorithm, the Levenberg-Marquardt algorithm, the Broyden-Fletcher-Goldfarb-Shanno algorithm, the gradient descent algorithm, the simulated annealing algorithm, the interior point algorithm, and the genetic algorithm, can be applied to find (\tilde{z}₁, \tilde{z}₂, . . . , \tilde{z}_{N}).

Here, the Gauss-Newton algorithm is used as an example. The Gauss-Newton algorithm is an iterative method applicable to a general non-linear multi-variable optimization problem. In the i-th iteration wherein the design variables (z₁, z₂, . . . , z_{N}) take values of (z₁ᵢ, z₂ᵢ, . . . , z_{Ni}), the Gauss-Newton algorithm linearizes fₚ (z₁, z₂, . . . , z_{N}) in the vicinity of (z₁ᵢ, z₂ᵢ, . . . , z_{Ni}), and then calculates values (z₁₍ᵢ₊₁₎, z₂₍ᵢ₊₁₎, . . . , z_{N(i+1)}) in the vicinity of (z₁ᵢ, z₂ᵢ, . . . , z_{Ni}) that give a minimum of CF(z₁, z₂, . . . , z_{N}). The design variables (z₁, z₂, . . . , z_{N}) take the values of (z₁₍ᵢ₊₁₎, z₂₍ᵢ₊₁₎, . . . , z_{N(i+1)}) in the (i+1)-th iteration. This iteration continues until convergence (i.e., CF(z₁, z₂, . . . , z_{N}) does not reduce any further) or a preset number of iterations is reached.

Specifically, in the i-th iteration, in the vicinity of (z₁ᵢ, z₂ᵢ, . . . , z_{Ni}),

$$\\ \begin{matrix}{{f}_{p} ( {z}_{1} , {z}_{2} , … , {z}_{N} ) \approx {f}_{p} ( {z}_{1 i} , {z}_{2 i} , … , {z}_{Ni} ) + {\sum }_{n = 1}^{N} \frac{\partial {f}_{p} ( {z}_{1} , {z}_{2} , … , {z}_{N} )}{\partial {z}_{n}} \vert}_{{z}_{1} = {z}_{1 i} , {z}_{2} = {z}_{2 i} , … {z}_{N} = {z}_{Ni}} ( {z}_{n} = {z}_{ni} ) & ( Eq . 3 )\end{matrix}$$

Under the approximation of Eq. 3, the cost function becomes:

$$\\ \begin{matrix}\begin{matrix}CF ( {z}_{1} , {z}_{2} , … , {z}_{N} ) = {\sum }_{p = 1}^{P} {w}_{p} {f}_{p}^{{}_{} 2} ( {z}_{1} , {z}_{2} , … , {z}_{N} ) = \\ {{{\sum }_{p = 1}^{P} {w}_{p} ( {f}_{p} ( {z}_{1 i} , {z}_{2 i} , … , {z}_{Ni} ) + {\sum }_{n = 1}^{N} \frac{\partial {f}_{p} ( {z}_{1} , {z}_{2} , … , {z}_{N} )}{\partial {z}_{n}} \vert}_{{z}_{1} = {z}_{1 i} , {z}_{2} = {z}_{2 i} , … {z}_{N} = {z}_{Ni}} ( {z}_{n} = {z}_{ni} ) )}^{2}\end{matrix} & ( Eq . 4 )\end{matrix}$$

which is a quadratic function of the design variables (z₁, z₂, . . . , z_{N}). Every term is constant except the design variables (z₁, z₂, . . . , z_{N}).

If the design variables (z₁, z₂, . . . , z_{N}) are not under any constraints, (z₁₍ᵢ₊₁₎, z₂₍ᵢ₊₁₎, . . . , z_{N(i+1)}) can be derived by solving N linear equations:

$$\\ \frac{\partial CF ( {z}_{1} , {z}_{2} , … , {z}_{N} )}{\partial {z}_{n}} = 0 ,$$

wherein n=1, 2, . . . , N.

If the design variables (z₁, z₂, . . . , z_{N}) are under constraints in the form of J inequalities (e.g. tuning ranges of (z₁, z₂, . . . , z_{N})) Σₙ₌₁^{N} Aₙⱼzₙ≤Bⱼ, for j=1, 2, . . . , J; and K equalities (e.g. interdependence between the design variables) Σₙ₌₁^{N} Cₙₖzₙ≤Dₖ, for k=1, 2, . . . , K, the optimization process becomes a classic quadratic programming problem, wherein Aₙⱼ, Bⱼ, Cₙₖ, Dₖ are constants. Additional constraints can be imposed for each iteration. For example, a “damping factor” Δ_{D}, can be introduced to limit the difference between (z₁₍ᵢ₊₁₎, z₂₍ᵢ₊₁₎, . . . , z_{N(i+1)}) and (z₁ᵢ, z₂ᵢ, . . . , z_{Ni}), so that the approximation of Eq. 3 holds. Such constraints can be expressed as zₙᵢ−Δ_{D}≤zₙ≤zₙᵢ+Δ_{D}. (z₁₍ᵢ₊₁₎, z₂₍ᵢ₊₁₎, . . . , z_{N(i+1)}) can be derived using, for example, methods described in Numerical Optimization (2^{nd} ed.) by Jorge Nocedal and Stephen J. Wright (Berlin New York: Vandenberghe. Cambridge University Press).

Instead of minimizing the RMS of fₚ (z₁, z₂, . . . , z_{N}), the optimization process can minimize magnitude of the largest deviation (the worst defect) among the evaluation points to their intended values. In this approach, the cost function can alternatively be expressed as

$$\\ \begin{matrix}CF ( {z}_{1} , {z}_{2} , … , {z}_{N} ) = {max}_{1 \leq p \leq P} \frac{{f}_{p} ( {z}_{1} , {z}_{2} , … , {z}_{N} )}{{CL}_{p}} & ( Eq . 5 )\end{matrix}$$

wherein CLₚ is the maximum allowed value for fₚ (z₁, z₂, . . . , z_{N}). This cost function represents the worst defect among the evaluation points. Optimization using this cost function minimizes magnitude of the worst defect. An iterative greedy algorithm can be used for this optimization.

The cost function of Eq. 5 can be approximated as:

$$\\ \begin{matrix}CF ( {z}_{1} , {z}_{2} , … , {z}_{N} ) = {\sum }_{p = 1}^{P} {{w}_{p} ( \frac{{f}_{p} ( {z}_{1} , {z}_{2} , … , {z}_{N} )}{{CL}_{p}} )}^{q} & ( Eq . 6 )\end{matrix}$$

wherein q is an even positive integer such as at least 4, or at least 10. Eq. 6 mimics the behavior of Eq. 5, while allowing the optimization to be executed analytically and accelerated by using methods such as the deepest descent method, the conjugate gradient method, etc.

Minimizing the worst defect size can also be combined with linearizing of fₚ (z₁, z₂, . . . , z_{N}). Specifically, fₚ(z₁, z₂, . . . , z_{N}) is approximated as in Eq. 3. Then the constraints on worst defect size are written as inequalities E_{Lp}≤fₚ(z₁, z₂, . . . , z_{N})≤E_{Up}, wherein E_{Lp} and E_{Up}, are two constants specifying the minimum and maximum allowed deviation for the fₚ (z₁, z₂, . . . , z_{N}). Plugging Eq. 3 in, these constraints are transformed to, for p=1, . . . P,

$$\\ \begin{matrix}\begin{matrix}{{\sum }_{n = 1}^{N} \frac{\partial {f}_{p} ( {z}_{1} , {z}_{2} , … , {z}_{N} )}{\partial {z}_{n}} \vert}_{{z}_{1} = {z}_{1 i} , {z}_{2} = {z}_{2 i} , … {z}_{N} = {z}_{Ni}} {z}_{n} \leq {E}_{Up} + \\ {{\sum }_{n = 1}^{N} \frac{\partial {f}_{p} ( {z}_{1} , {z}_{2} , … , {z}_{N} )}{\partial {z}_{n}} \vert}_{{z}_{1} = {z}_{1 i} , {z}_{2} = {z}_{2 i} , … {z}_{N} = {z}_{Ni}} {z}_{ni} - \\ {f}_{p} ( {z}_{1 i} , {z}_{2 i} , … , {z}_{Ni} )\end{matrix} & ( Eq . 6 ’ )\end{matrix}$$

$$\\ \begin{matrix}\begin{matrix}{And - {\sum }_{n = 1}^{N} \frac{\partial {f}_{p} ( {z}_{1} , {z}_{2} , … , {z}_{N} )}{\partial {z}_{n}} \vert}_{{z}_{1} = {z}_{1 i} , {z}_{2} = {z}_{2 i} , … {z}_{N} = {z}_{Ni}} {z}_{n} \leq - {E}_{Up} - \\ {{\sum }_{n = 1}^{N} \frac{\partial {f}_{p} ( {z}_{1} , {z}_{2} , … , {z}_{N} )}{\partial {z}_{n}} \vert}_{{z}_{1} = {z}_{1 i} , {z}_{2} = {z}_{2 i} , … {z}_{N} = {z}_{Ni}} {z}_{ni} + \\ {f}_{p} ( {z}_{1 i} , {z}_{2 i} , … , {z}_{Ni} )\end{matrix} & ( Eq . 6 ’ ’ )\end{matrix}$$

Since Eq. 3 is generally valid only in the vicinity of (z₁, z₂, . . . , z_{N}), in case the desired constraints E_{Lp}≤fₚ(z₁, z₂, . . . , z_{N})≤E_{Up} cannot be achieved in such vicinity, which can be determined by any conflict among the inequalities, the constants E_{Lp} and E_{Up} can be relaxed until the constraints are achievable. This optimization process minimizes the worst defect size in the vicinity of (z₁, z₂, . . . , z_{N}), i. Then each step reduces the worst defect size gradually, and each step is executed iteratively until certain terminating conditions are met. This will lead to optimal reduction of the worst defect size.

Another way to minimize the worst defect is to adjust the weight wₚ in each iteration. For example, after the i-th iteration, if the r-th evaluation point is the worst defect, wᵣ can be increased in the (i+1)-th iteration so that the reduction of that evaluation point's defect size is given higher priority.

In addition, the cost functions in Eq. 4 and Eq. 5 can be modified by introducing a Lagrange multiplier to achieve compromise between the optimization on RMS of the defect size and the optimization on the worst defect size, i.e.,

$$\\ \begin{matrix}CF ( {z}_{1} , {z}_{2} , … , {z}_{N} ) = ( 1 - λ ) {\sum }_{p = 1}^{P} {w}_{p} {f}_{p}^{{}_{} 2} ( {z}_{1} , {z}_{2} , … , {z}_{N} ) + λ {max}_{1 \leq p \leq P} \frac{{f}_{p} ( {z}_{1} , {z}_{2} , … , {z}_{N} )}{{CL}_{p}} & ( Eq . 6 ’ ’ ’ )\end{matrix}$$

where λ is a preset constant that specifies the trade-off between the optimization on RMS of the defect size and the optimization on the worst defect size. In particular, if λ=0, then this becomes Eq. 4 and the RMS of the defect size is only minimized; while if λ=1, then this becomes Eq. 5 and the worst defect size is only minimized; if 0<λ<1, then both are taken into consideration in the optimization. Such optimization can be solved using multiple methods. For example, the weighting in each iteration may be adjusted, similar to the one described previously. Alternatively, similar to minimizing the worst defect size from inequalities, the inequalities of Eq. 6′ and 6″ can be viewed as constraints of the design variables during solution of the quadratic programming problem. Then, the bounds on the worst defect size can be relaxed incrementally or increase the weight for the worst defect size incrementally, compute the cost function value for every achievable worst defect size, and choose the design variable values that minimize the total cost function as the initial point for the next step. By doing this iteratively, the minimization of this new cost function can be achieved.

Optimizing a lithographic projection apparatus can expand the process window. A larger process window provides more flexibility in process design and chip design. The process window can be defined as, for example, a set of focus, dose, aberration, laser bandwidth (e.g., E95 or (λ min to λ max) and fare specific to intensity values for which the resist image is within a certain limit of the design target of the resist image. Note that all the methods discussed here may also be extended to a generalized process window definition that can be established by different or additional base parameters than exposure dose and defocus. These may include, but are not limited to, optical settings such as NA, sigma, aberration, polarization, or an optical constant of the resist layer. For example, as described earlier, if the process window (PW) also comprises different patterning device pattern bias (mask bias), then the optimization includes the minimization of Mask Error Enhancement Factor (MEEF), which is defined as the ratio between the substrate edge placement error (EPE) and the induced patterning device pattern edge bias. The process window defined on focus and dose values only serve as an example in this disclosure.

A method of maximizing a process window using, for example, dose and focus as its parameters, according to an embodiment, is described below. In a first step, starting from a known condition (f₀, ε₀) in the process window, wherein f₀ is a nominal focus and ε₀ is a nominal dose, minimizing one of the cost functions below in the vicinity (f₀±Δf, ε₀±ε):

$$\\ \begin{matrix}CF ( {z}_{1} , {z}_{2} , … , {z}_{N ,} {f}_{0} , {ε}_{0} ) = {max}_{( f , ε ) = ( {f}_{0} \pm Δ f , {ε}_{0} \pm ε )} {max}_{p} \vert {f}_{p} ( {z}_{1} , {z}_{2} , … , {z}_{N} , f , ε ) \vert or & ( Eq . 7 )\end{matrix}$$

$$\\ \begin{matrix}CF ( {z}_{1} , {z}_{2} , … , {z}_{N ,} {f}_{0} , {ε}_{0} ) = {\sum }_{( f , ε ) = ( {f}_{0} \pm Δ f , {ε}_{0} \pm ε )} {\sum }_{p} {w}_{p} {f}_{p}^{{}_{} 2} ( {z}_{1} , {z}_{2} , … , {z}_{N} , f , ε ) or & ( Eq . 7 ’ )\end{matrix}$$

$$\\ \begin{matrix}CF ( {z}_{1} , {z}_{2} , … , {z}_{N ,} {f}_{0} , {ε}_{0} ) = ( 1 - λ ) {\sum }_{( f , ε ) = ( {f}_{0} \pm Δ f , {ε}_{0} \pm ε )} {\sum }_{p} {w}_{p} {f}_{p}^{{}_{} 2} ( {z}_{1} , {z}_{2} , … , {z}_{N} , f , ε ) + λ {max}_{( f , ε ) = ( {f}_{0} \pm Δ f , {ε}_{0} \pm ε )} {max}_{p} \vert {f}_{p} ( {z}_{1} , {z}_{2} , … , {z}_{N} , f , ε ) \vert & ( Eq . 7 ’ ’ )\end{matrix}$$

If the nominal focus f₀ and nominal dose ε₀ are allowed to shift, they can be optimized jointly with the design variables (z₁, z₂, . . . , z_{N}). In the next step, (f₀±Δf, ε₀±ε) is accepted as part of the process window, if a set of values of (z₁, z₂, . . . , z_{N}, f, ε) can be found such that the cost function is within a preset limit.

If the focus and dose are not allowed to shift, the design variables (z₁, z₂, . . . , z_{N}) are optimized with the focus and dose fixed at the nominal focus f₀ and nominal dose ε₀. In an alternative embodiment. (f₀±Δf, ε₀±ε) is accepted as part of the process window, if a set of values of (z₁, z₂, . . . , z_{N}) can be found such that the cost function is within a preset limit.

The methods described earlier in this disclosure can be used to minimize the respective cost functions of Eqs. 7, 7′, or 7″. If the design variables represent one or more characteristics of the projection optics, such as the Zernike coefficients, then minimizing the cost functions of Eqs. 7, 7′, or 7″ leads to process window maximization based on projection optics optimization, i.e., LO. If the design variables represent one or more characteristics of the illumination and patterning device in addition to those of the projection optics, then minimizing the cost function of Eqs. 7, 7′, or 7″ leads to process window maximizing based on SMLO, as illustrated in FIG. 10. If the design variables represented one or more characteristics of the source and patterning device, then minimizing the cost functions of Eqs. 7, 7′, or 7″ leads to process window maximization based on SMO. The cost functions of Eqs. 7, 7′, or 7″ can also include at least one fₚ (z₁, z₂, . . . , z_{N}) such as described herein, that is a function of the bandwidth.

FIG. 13 shows one specific example of how a simultaneous SMLO process can use a gradient based optimization (e.g., quasi newton, or Gauss Newton Algorithm). In step S702, starting values of one or more design variables are identified. A tuning range for each variable may also be identified. In step S704, the cost function is defined using the one or more design variables. In step S706, the cost function is expanded around the starting values for all evaluation points in the design layout. In step S708, a suitable optimization technique is applied to minimize or maximize the cost function. In optional step S710, a full-chip simulation is executed to cover all critical patterns in a full-chip design layout. A desired lithographic response metric (such as CD, EPE, or EPE and PPE) is obtained in step S714, and compared with predicted values of those quantities in step S712. In step S716, a process window is determined. Steps S718, S720, and S722 are similar to corresponding steps S514, S516 and S518, as described with respect to FIG. 12A. As mentioned before, the final output may be, for example, a wavefront aberration map in the pupil plane, optimized to produce the desired imaging performance. The final output may be, for example, an optimized illumination map and/or an optimized design layout.

FIG. 12B shows an exemplary method to optimize the cost function where the design variables (z₁, z₂, . . . , z_{N}) include design variables that may only assume discrete values.

The method starts by defining the pixel groups of the illumination and the patterning device tiles of the patterning device (step S802). Generally, a pixel group or a patterning device tile may also be referred to as a division of a lithographic process component. In one exemplary approach, the illumination is divided into 117 pixel groups, and 94 patterning device tiles are defined for the patterning device, substantially as described above, resulting in a total of 211 divisions.

In step S804, a lithographic model is selected as the basis for lithographic simulation. A lithographic simulation produces results that are used in calculations of one or more lithographic metrics, or responses. A particular lithographic metric is defined to be the performance metric that is to be optimized (step S806). In step S808, the initial (pre-optimization) conditions for the illumination and the patterning device are set up. Initial conditions include initial states for the pixel groups of the illumination and the patterning device tiles of the patterning device such that references may be made to an initial illumination shape and an initial patterning device pattern. Initial conditions may also include patterning device pattern bias (sometimes referred to as mask bias), NA, and/or focus ramp range. Although steps S802, S804, S806, and S808 are depicted as sequential steps, it will be appreciated that in other embodiments, these steps may be performed in other sequences.

In step S810, the pixel groups and patterning device tiles are ranked. Pixel groups and patterning device tiles may be interleaved in the ranking. Various ways of ranking may be employed, including: sequentially (e.g., from pixel group 1 to pixel group 117 and from patterning device tile 1 to patterning device tile 94), randomly, according to the physical locations of the pixel groups and patterning device tiles (e.g., ranking pixel groups closer to the center of the illumination higher), and/or according to how an alteration of the pixel group or patterning device tile affects the performance metric.

Once the pixel groups and patterning device tiles are ranked, the illumination and patterning device are adjusted to improve the performance metric (step S812). In step S812, each of the pixel groups and patterning device tiles are analyzed, in order of ranking, to determine whether an alteration of the pixel group or patterning device tile will result in an improved performance metric. If it is determined that the performance metric will be improved, then the pixel group or patterning device tile is accordingly altered, and the resulting improved performance metric and modified illumination shape or modified patterning device pattern form the baseline for comparison for subsequent analyses of lower-ranked pixel groups and patterning device tiles. In other words, alterations that improve the performance metric are retained. As alterations to the states of pixel groups and patterning device tiles are made and retained, the initial illumination shape and initial patterning device pattern changes accordingly, so that a modified illumination shape and a modified patterning device pattern result from the optimization process in step S812.

In other approaches, patterning device polygon shape adjustments and pairwise polling of pixel groups and/or patterning device tiles are also performed within the optimization process of S812.

In an embodiment, the interleaved simultaneous optimization procedure may include altering a pixel group of the illumination and if an improvement of the performance metric is found, the dose or intensity is stepped up and/or down to look for further improvement. In a further embodiment, the stepping up and/or down of the dose or intensity may be replaced by a bias change of the patterning device pattern to look for further improvement in the simultaneous optimization procedure.

In step S814, a determination is made as to whether the performance metric has converged. The performance metric may be considered to have converged, for example, if little or no improvement to the performance metric has been witnessed in the last several iterations of steps S810 and S812. If the performance metric has not converged, then the steps of S810 and S812 are repeated in the next iteration, where the modified illumination shape and modified patterning device from the current iteration are used as the initial illumination shape and initial patterning device for the next iteration (step S816).

The optimization methods described above may be used to increase the throughput of the lithographic projection apparatus. For example, the cost function may include a fₚ (z₁, z₂, . . . , z_{N}) that is a function of the exposure time. In an embodiment, optimization of such a cost function is constrained or influenced by a measure of the bandwidth or other metric.

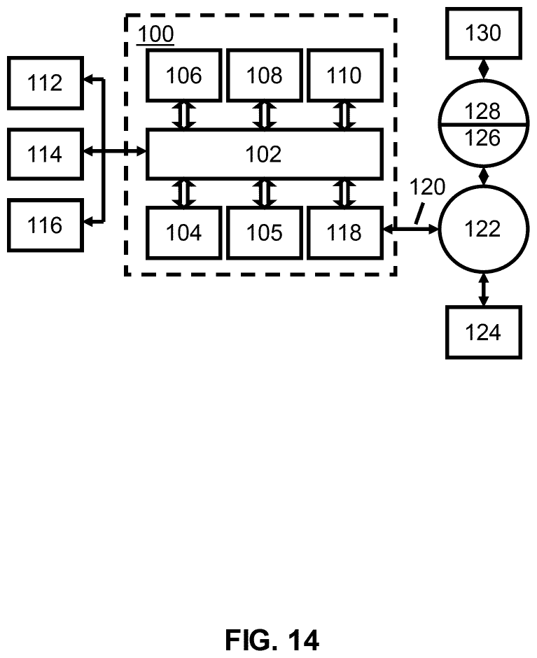

FIG. 14 is a block diagram that illustrates a computer system 100 which can assist in implementing the optimization methods and flows disclosed herein. Computer system 100 includes a bus 102 or other communication mechanism for communicating information, and a processor 104 (or multiple processors 104 and 105) coupled with bus 102 for processing information. Computer system 100 also includes a main memory 106, such as a random access memory (RAM) or other dynamic storage device, coupled to bus 102 for storing information and instructions to be executed by processor 104. Main memory 106 also may be used for storing temporary variables or other intermediate information during execution of instructions to be executed by processor 104. Computer system 100 further includes a read only memory (ROM) 108 or other static storage device coupled to bus 102 for storing static information and instructions for processor 104. A storage device 110, such as a magnetic disk or optical disk, is provided and coupled to bus 102 for storing information and instructions.

Computer system 100 may be coupled via bus 102 to a display 112, such as a cathode ray tube (CRT) or flat panel or touch panel display for displaying information to a computer user. An input device 114, including alphanumeric and other keys, is coupled to bus 102 for communicating information and command selections to processor 104. Another type of user input device is cursor control 116, such as a mouse, a trackball, or cursor direction keys for communicating direction information and command selections to processor 104 and for controlling cursor movement on display 112. This input device typically has two degrees of freedom in two axes, a first axis (e.g., x) and a second axis (e.g., y), that allows the device to specify positions in a plane. A touch panel (screen) display may also be used as an input device.

According to one embodiment, portions of the optimization process may be performed by computer system 100 in response to processor 104 executing one or more sequences of one or more instructions contained in main memory 106. Such instructions may be read into main memory 106 from another computer-readable medium, such as storage device 110. Execution of the sequences of instructions contained in main memory 106 causes processor 104 to perform the process steps described herein. One or more processors in a multi-processing arrangement may also be employed to execute the sequences of instructions contained in main memory 106. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 104 for execution. Such a medium may take many forms, including but not limited to, non-volatile media, volatile media, and transmission media. Non-volatile media include, for example, optical or magnetic disks, such as storage device 110. Volatile media include dynamic memory, such as main memory 106. Transmission media include coaxial cables, copper wire and fiber optics, including the wires that comprise bus 102. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 104 for execution. For example, the instructions may initially be borne on a magnetic disk of a remote computer. The remote computer can load the instructions into its dynamic memory and send the instructions over a telephone line using a modem. A modem local to computer system 100 can receive the data on the telephone line and use an infrared transmitter to convert the data to an infrared signal. An infrared detector coupled to bus 102 can receive the data carried in the infrared signal and place the data on bus 102. Bus 102 carries the data to main memory 106, from which processor 104 retrieves and executes the instructions. The instructions received by main memory 106 may optionally be stored on storage device 110 either before or after execution by processor 104.

Computer system 100 may also include a communication interface 118 coupled to bus 102. Communication interface 118 provides a two-way data communication coupling to a network link 120 that is connected to a local network 122. For example, communication interface 118 may be an integrated services digital network (ISDN) card or a modem to provide a data communication connection to a corresponding type of telephone line. As another example, communication interface 118 may be a local area network (LAN) card to provide a data communication connection to a compatible LAN. Wireless links may also be implemented. In any such implementation, communication interface 118 sends and receives electrical, electromagnetic or optical signals that carry digital data streams representing various types of information.

Network link 120 typically provides data communication through one or more networks to other data devices. For example, network link 120 may provide a connection through local network 122 to a host computer 124 or to data equipment operated by an Internet Service Provider (ISP) 126. ISP 126 in turn provides data communication services through the worldwide packet data communication network, now commonly referred to as the “Internet” 128. Local network 122 and Internet 128 both use electrical, electromagnetic or optical signals that carry digital data streams. The signals through the various networks and the signals on network link 120 and through communication interface 118, which carry the digital data to and from computer system 100, are exemplary forms of carrier waves transporting the information.

Computer system 100 can send messages and receive data, including program code, through the network(s), network link 120, and communication interface 118. In the Internet example, a server 130 might transmit a requested code for an application program through Internet 128, ISP 126, local network 122 and communication interface 118. One such downloaded application may provide for the illumination optimization of the embodiment, for example. The received code may be executed by processor 104 as it is received, and/or stored in storage device 110, or other non-volatile storage for later execution. In this manner, computer system 100 may obtain application code in the form of a carrier wave.

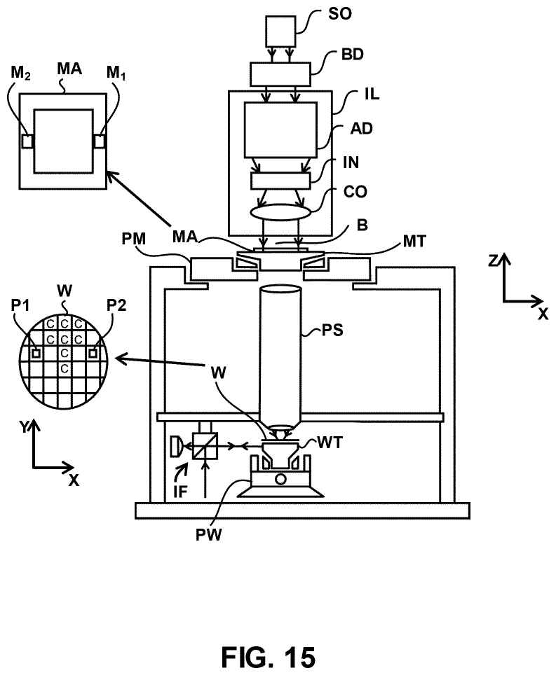

FIG. 15 schematically depicts an exemplary lithographic projection apparatus whose illumination could be optimized utilizing the methods described herein. The apparatus comprises:
an illumination system IL, to condition a beam B of radiation. In this particular case, the illumination system also comprises a radiation source SO;
a first object table (e.g., patterning device table) MT provided with a patterning device holder to hold a patterning device MA (e.g., a reticle), and connected to a first positioner to accurately position the patterning device with respect to item PS;
a second object table (substrate table) WT provided with a substrate holder to hold a substrate W (e.g., a resist-coated silicon wafer), and connected to a second positioner to accurately position the substrate with respect to item PS;
a projection system (“lens”) PS (e.g., a refractive, catoptric or catadioptric optical system) to image an irradiated portion of the patterning device MA onto a target portion C (e.g., comprising one or more dies) of the substrate W.

As depicted herein, the apparatus is of a transmissive type (i.e., has a transmissive patterning device). However, in general, it may also be of a reflective type, for example (with a reflective patterning device). The apparatus may employ a different kind of patterning device to classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning means, such as a beam expander Ex, for example. The illuminator IL may comprise adjusting means AD for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

It should be noted with regard to FIG. 15 that the source SO may be within the housing of the lithographic projection apparatus (as is often the case when the source SO is a mercury lamp, for example), but that it may also be remote from the lithographic projection apparatus, the radiation beam that it produces being led into the apparatus (e.g., with the aid of suitable directing mirrors); this latter scenario is often the case when the source SO is an excimer laser (e.g., based on KrF, ArF or F₂ lasing).

The beam PB subsequently intercepts the patterning device MA, which is held on a patterning device table MT. Having traversed the patterning device MA, the beam B passes through the lens PL, which focuses the beam B onto a target portion C of the substrate W. With the aid of the second positioning means (and interferometric measuring means IF), the substrate table WT can be moved accurately, e.g., so as to position different target portions C in the path of the beam PB. Similarly, the first positioning means can be used to accurately position the patterning device MA with respect to the path of the beam B. e.g., after mechanical retrieval of the patterning device MA from a patterning device library, or during a scan. In general, movement of the object tables MT, WT will be realized with the aid of a long-stroke module (coarse positioning) and a short-stroke module (fine positioning), which are not explicitly depicted in FIG. 15. However, in the case of a stepper (as opposed to a step-and-scan tool) the patterning device table MT may just be connected to a short stroke actuator, or may be fixed.

The depicted tool can be used in two different modes:
In step mode, the patterning device table MT is kept essentially stationary, and an entire patterning device image is projected in one go (i.e., a single “flash”) onto a target portion C. The substrate table WT is then shifted in the x and/or y directions so that a different target portion C can be irradiated by the beam PB;
In scan mode, essentially the same scenario applies, except that a given target portion C is not exposed in a single “flash”. Instead, the patterning device table MT is movable in a given direction (the so-called “scan direction”, e.g., the y direction) with a speed v, so that the projection beam B is caused to scan over a patterning device image; concurrently, the substrate table WT is simultaneously moved in the same or opposite direction at a speed V=Mv, in which M is the magnification of the lens PL (typically, M=¼ or ⅕). In this manner, a relatively large target portion C can be exposed, without having to compromise on resolution.

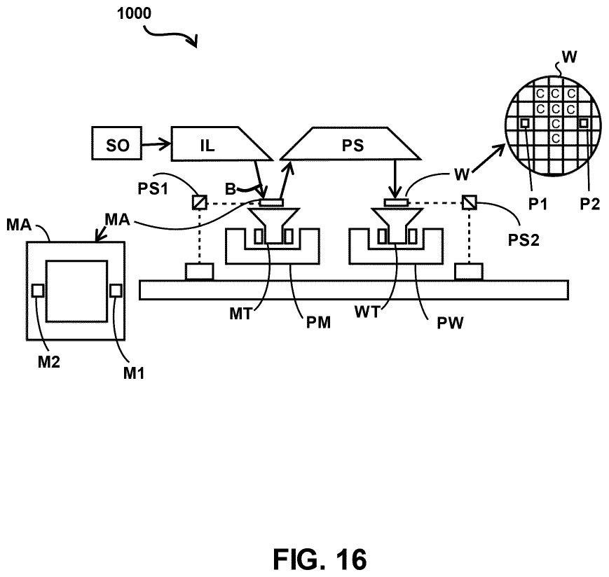

FIG. 16 schematically depicts another exemplary lithographic projection apparatus 1000 whose illumination could be optimized utilizing the methods described herein.

The lithographic projection apparatus 1000 comprises:
a source collector module SO
an illumination system (illuminator) IL configured to condition a radiation beam B (e.g., EUV radiation).
a support structure (e.g., a patterning device table) MT constructed to support a patterning device (e.g., a mask or a reticle) MA and connected to a first positioner PM configured to accurately position the patterning device;
a substrate table (e.g., a wafer table) WT constructed to hold a substrate (e.g., a resist coated wafer) W and connected to a second positioner PW configured to accurately position the substrate; and
a projection system (e.g., a reflective projection system) PS configured to project a pattern imparted to the radiation beam B by patterning device MA onto a target portion C (e.g., comprising one or more dies) of the substrate W.

As here depicted, the apparatus 1000 is of a reflective type (e.g., employing a reflective patterning device). It is to be noted that because most materials are absorptive within the EUV wavelength range, the patterning device may have multilayer reflectors comprising, for example, a multi-stack of Molybdenum and Silicon. In one example, the multi-stack reflector has a 40 layer pairs of Molybdenum and Silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Referring to FIG. 16, the illuminator IL receives an extreme ultra-violet radiation beam from the source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. The source collector module SO may be part of an EUV radiation system including a laser, not shown in FIG. 16, for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser is not considered to form part of the lithographic apparatus and the radiation beam is passed from the laser to the source collector module with the aid of a beam delivery system comprising, for example, suitable directing mirrors and/or a beam expander. In other cases, the source may be an integral part of the source collector module, for example when the source is a discharge produced plasma EUV generator, often termed as a DPP source.

The illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B is incident on the patterning device (e.g., mask) MA, which is held on the support structure (e.g., patterning device table) MT, and is patterned by the patterning device. After being reflected from the patterning device (e.g., mask) MA, the radiation beam B passes through the projection system PS, which focuses the beam onto a target portion C of the substrate W. With the aid of the second positioner PW and position sensor PS2 (e.g., an interferometric device, linear encoder or capacitive sensor), the substrate table WT can be moved accurately, e.g., so as to position different target portions C in the path of the radiation beam B. Similarly, the first positioner PM and another position sensor PS1 can be used to accurately position the patterning device (e.g., mask) MA with respect to the path of the radiation beam B. Patterning device (e.g., mask) MA and substrate W may be aligned using patterning device alignment marks M1, M2 and substrate alignment marks P1. P2.

The depicted apparatus 1000 could be used in at least one of the following modes:
1. In step mode, the support structure (e.g., patterning device table) MT and the substrate table WT are kept essentially stationary, while an entire pattern imparted to the radiation beam is projected onto a target portion C at one time (i.e., a single static exposure). The substrate table WT is then shifted in the X and/or Y direction so that a different target portion C can be exposed.
2. In scan mode, the support structure (e.g., patterning device table) MT and the substrate table WT are scanned synchronously while a pattern imparted to the radiation beam is projected onto a target portion C (i.e., a single dynamic exposure). The velocity and direction of the substrate table WT relative to the support structure (e.g., patterning device table) MT may be determined by the (de-)magnification and image reversal characteristics of the projection system PS.
3. In another mode, the support structure (e.g., patterning device table) MT is kept essentially stationary holding a programmable patterning device, and the substrate table WT is moved or scanned while a pattern imparted to the radiation beam is projected onto a target portion C. In this mode, generally a pulsed radiation source is employed, and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

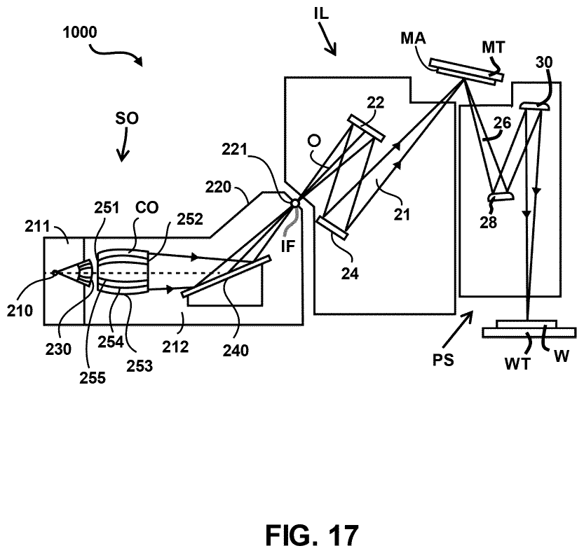

FIG. 17 shows the apparatus 1000 in more detail, including the source collector module SO, the illumination system IL, and the projection system PS. The source collector module SO is constructed and arranged such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, an electrical discharge causing an at least partially ionized plasma. Partial pressures of, for example, 10 Pa of Xe, Li. Sn vapor or any other suitable gas or vapor may be required for efficient generation of the radiation. In an embodiment, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure, as known in the art.

The collector chamber 211 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused on a virtual source point IF along the optical axis indicated by the dot-dashed line ‘O’. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the beam of radiation 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in illumination optics unit IL and projection system PS. The grating spectral filter 240 may optionally be present, depending upon the type of lithographic apparatus. Further, there may be more mirrors present than those shown in the figures, for example there may be 1-6 additional reflective elements present in the projection system PS than shown in FIG. 17.

Collector optic CO, as illustrated in FIG. 17, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type may be used in combination with a discharge produced plasma source, often called a DPP source.

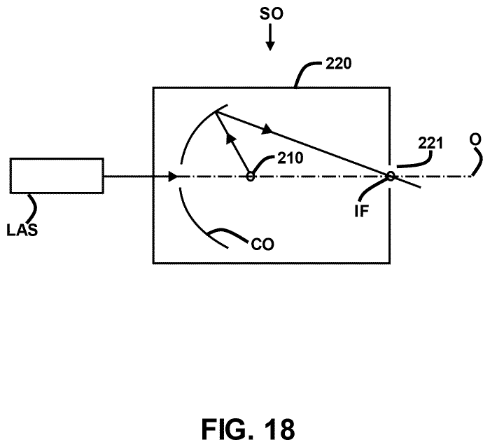

Alternatively, the source collector module SO may be part of an LPP radiation system as shown in FIG. 18. A laser LA is arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.

The concepts disclosed herein may simulate or mathematically model any generic imaging system for imaging sub wavelength features and may be especially useful with emerging imaging technologies capable of producing increasingly shorter wavelengths. Emerging technologies already in use include EUV (extreme ultra-violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

Embodiments of the present disclosure can be further described in the following clauses.
1. A non-transitory computer-readable medium configured for determining mask rule check violations associated with mask features, the medium comprising instructions stored therein that, when executed by one or more processors, cause operations comprising:
   obtaining a detector having geometric properties corresponding to a mask rule check (MRC), the detector configured to include a curved portion to detect a curvature violation, an enclosed area, a predefined orientation axis configured to guide relative positioning of the detector with a mask feature, and a length along the orientation axis to detect a critical dimension violation;
   aligning the orientation axis of the detector with a normal axis at a location on the mask feature to cause the length of the detector to extend along a prescribed axis of the location on the mask feature; and
   identifying, based on the orientation axis of the detector aligned with the prescribed axis of the mask feature, an MRC violation corresponding to a region of the mask feature that intersects the enclosed area, wherein the aligning and geometry of the detector causes the detector to intersect the region of mask feature to identify the curvature violation, and/or the critical dimension violation.
2. The medium of clause 1, wherein the detector is non-circular and has at least a first curved portion and a second curved portion, wherein the first curved portion has a first radius of curvature, wherein the second curved portion has a second radius of curvature, and wherein the first radius is different from the second radius.
3. The medium of clause 2, wherein the non-circular detector is configured to have an elliptical shape having a radius of curvature configured to detect a curvature violation and a length along an orientation axis configured to detect a critical dimension violation.
4. The medium of clause 3, wherein the curved portion of the detector has a shape and size corresponding to a curvature of a tip portion of the mask feature, and a minimum size of the mask feature defined by mask manufacturability check.
5. The medium of clause 1, wherein the identifying comprises:
determining MRC violations including a curvature violation and a critical dimension violation based on the intersection of the detector with the mask feature at a single position.
6. The medium of clause 1, wherein the identifying comprises:
determining MRC violations associated with a curvature violation and a space violation based on intersection between at least two mask features at a single position.
7. The medium of any one of clauses 1-6, wherein obtaining of the detector comprises:
obtaining the length of the detector along the orientation axis, the length being a distance between points of intersection of the orientation axis with a boundary of the detector upon extending the orientation axis.
8. The medium of any one of clauses 1-7, wherein the prescribed axis corresponds to a normal axis of the location on the mask feature, wherein aligning the orientation axis of the detector with the prescribed axis of the mask feature comprises:
identifying the normal axis at the location of the mask feature, the normal axis being perpendicular to a curved at the location of the mask feature; contacting an edge of the detector with an edge of the feature at the location; and orienting the orientation axis of the detector with the normal axis at the location of the feature.
9. The medium of any one of clauses 1-7, wherein identifying the MRC violation comprises: determining the MRC violation by sliding the detector along an edge of the mask feature while maintaining the orientation axis of the detector aligned to a normal axis at each location of the mask feature.
10. The medium of clause 9, wherein identifying the MRC violation comprises:
   (a) aligning the orientation axis of the detector with a first normal axis at a first location of the mask feature;
   (b) identifying, based on the orientation axis of the detector aligned with the first normal axis of the mask feature, whether a region of the mask feature around the first location is inside the enclosed area;
   (c) responsive to the region of the mask feature being inside the enclosed area, flagging the first location as the MRC location; and
   (d) responsive to the region of the mask feature not being inside the enclosed area, sliding the detector to a second location of the mask feature, and identifying the MRC violation by performing steps (a)-(c) at the second location and a second normal axis thereof.
11. The medium of any one of clauses 1-10, wherein the obtaining of the detector comprises:
   accessing, from a library of detectors, the detector for determining MRC violation of the mask feature.
12. The medium of clause 11, wherein the library of detectors include a plurality of detectors, each detector having a different shape and size than other detectors.
13. The medium of any one of clauses 1-12, further comprising:
performing, based on the detector, a mask design to determine shape and size of mask features of the mask design.
14. The medium of clause 13, wherein performing of the mask design comprising:
   (a) simulating, using a design layout, a mask optimization process to determine the mask features for the mask design, the design layout corresponding to features to be printed on a semiconductor chip;
   (b) determining, via the detector, portions of the mask features that violate the MRC; and
   (c) responsive to violating the MRC, modifying the corresponding portions of the mask features to satisfy the MRC; and repeating steps (a)-(c).
15. The medium of clause 14, the mask optimization process comprises: a mask only optimization process, a source mask optimization process, and/or an optical proximity correction process.
16. The medium of any one of clauses 1-15, wherein the mask feature is curvilinear in shape.
17. The medium of any one of clauses 1-16, wherein the MRC comprises one or more geometric properties associated with the mask feature, the geometric properties comprising at least one of: a minimum CD of a mask feature that can be manufactured, a minimum curvature of mask feature that can be manufactured, or a minimum space between two features that can be manufactured.
18. The medium of any one of clauses 1-17, wherein the orientation axis is perpendicular to a point of the curved portion of the detector.
19. The medium of any one of clauses 1-18, wherein the enclosed area of the detector comprises: a fully enclosed area or a partially enclosed area having an opening.
20. A non-transitory computer-readable medium configured for determining mask rule check violations associated with mask features, the medium comprising instructions stored therein that, when executed by one or more processors, cause operations comprising: obtaining a non-circular detector having geometric properties corresponding to a mask rule check (MRC), the non-circular detector configured to include a curved portion to detect a curvature violation, an enclosed area, an orientation axis that is perpendicular to a point of the curved portion, and a length along the orientation axis to detect a critical dimension violation;
aligning the orientation axis with a prescribed axis of a location on a mask feature to cause the length of the non-circular detector to extend along the prescribed axis of the mask feature; and identify, based on the aligned non-circular detector and the mask feature, an MRC violation corresponding to a region of the mask feature that intersects the enclosed area, wherein the aligning and geometry of the non-circular detector causes the detector to intersect the region of mask feature to identify the curvature violation, and/or the critical dimension violation.
21. The medium of clause 20, wherein the non-circular detector has at least a first curved portion and a second curved portion, wherein the first curved portion has a first radius of curvature, wherein the second curved portion has a second radius of curvature, and wherein the first radius is different from the second radius.
22. The medium of clause 21, wherein the non-circular detector is configured to have an elliptical shape with a radius of curvature configured to detect a curvature violation and a length along an orientation axis configured to detect a critical dimension violation.
23. The medium of clause 20, wherein obtaining of the non-circular detector comprises:
receiving the detector that is shaped based on feature size, and a curvature of the mask feature that can be manufactured.
24. The medium of clause 23, wherein the curved portion of the non-circular detector has a shape and size corresponding to a curvature of a tip portion of the mask feature, and a minimum size of the mask feature that can be manufactured.
25. The medium of clause 20, wherein the identifying comprises:
determining MRC violations including a curvature violation and a critical dimension violation based on the intersection of the non-circular detector with the mask feature at a single position.
26. The medium of clause 20, wherein the identifying comprises:
determining MRC violations associated with a curvature violation and a space violation based on intersection between at least two mask features at a single position.
27. The medium of any one of clause 20-26, wherein obtaining of the detector comprises: obtaining the length of the detector along the orientation axis, the length being a distance between points of intersection of the orientation axis with a boundary of the detector upon extending the orientation axis.
28. The medium of any one of clauses 20-27, wherein the prescribed axis corresponds to a normal axis of the location on the mask feature, wherein aligning the orientation axis comprises: determining the normal axis at the location of the mask feature;
contacting an edge of the non-circular detector with an edge of the feature at the location; and orienting the orientation axis of the non-circular detector with the normal axis at the location of the feature.
29. The medium of any one of clauses 20-27, wherein identifying the MRC violation comprises: determining the MRC violation by sliding the non-circular detector along an edge of the mask feature while maintaining the orientation axis of the non-circular detector aligned to a normal axis of each location of the mask feature.
30. The medium of clause 29, wherein identifying the MRC violation comprises:
   (a) aligning the orientation axis of the non-circular detector with a first normal axis at a first location of the mask feature;
   (b) identifying, based on the orientation axis of the detector aligned with the normal axis of the mask feature, whether a region of the mask feature around the first location is inside the enclosed area;
   (c) responsive to the region of the mask feature being inside the enclosed area, flagging the first location as the MRC location; and
   (d) responsive to the region of the mask feature not being inside the enclosed area, sliding the non-circular detector to a second location of the mask feature, and identifying the MRC violation by performing steps (a)-(c) at the second location and a second normal axis thereof.
31. The medium of any one of clauses 20-30, wherein the obtaining of the non-circular detector comprises:
accessing, from a library of detectors, the non-circular detector for determining MRC violation of the mask feature.
32. The medium of clause 10, wherein the library of detectors include a plurality of non-circular detectors, each non-circular detector having a different shape and size than other detectors.
33. The medium of any one of clauses 20-32, wherein the mask feature is curvilinear in shape.
34. The medium of any one of clauses 20-23, further comprising:
performing, based on the non-circular detector, a mask design to determine shape and size of mask features of the mask design.
35. The medium of clause 34, wherein performing of the mask design comprising:
   (a) simulating, using a design layout, a mask optimization process to determine the mask features for the mask design, the design layout corresponding to features to be printed on a semiconductor chip;
   (b) determining, via the non-circular detector, portions of the mask features that violate the MRC; and
   (c) responsive to violating the MRC, modifying the corresponding portions of the mask features to satisfy the MRC; and repeating steps (a)-(c).
36. The medium of clause 35, the mask optimization process comprises: a mask optimization process, a source mask optimization process, and/or an optical proximity correction process.
37. The medium of any one of clauses 20-36, wherein the MRC includes one or more geometric properties associated with the mask feature, the geometric properties comprising at least one of: a minimum CD of a mask feature that can be manufactured, a minimum curvature of mask feature that can be manufactured, or a minimum space between two features that can be manufactured.
38. The medium of any one of clauses 20-37, wherein the enclosed area of the detector comprises: a fully enclosed area or a partially enclosed area having an opening.
39. A non-transitory computer-readable medium configured for determining a mask design for manufacturing a mask to be employed in a semiconductor manufacturing, the medium comprising instructions stored therein that, when executed by one or more processors, cause operations comprising:
simulating, using a design layout, a mask optimization process to determine mask features for the mask design, the design layout corresponding to features to be printed on a semiconductor chip; and
determining, via a detector, portions of the mask features that violate a mask rule check (MRC), the detector configured to have a curved portion, an enclosed area, and an orientation axis that is perpendicular to a point of the curved portion, the orientation axis for guiding an orientation of the detector with respect to a mask feature to detect MRC violations; and responsive to the portions violating the MRC, modifying the corresponding portions of the mask features to satisfy the MRC.
40. The medium of clause 39, the determining the portions of the mask features that violate the MRC comprises: obtaining the detector having geometric properties corresponding to the MRC; aligning the orientation axis with a prescribed axis of a location on a mask feature; and identifying, based on the orientation axis of the detector and the prescribed axis of the mask feature, the MRC violation corresponding to a region of the mask feature that intersects the enclosed area.
41. The medium of clause 39, wherein the detector is non-circular and has a first curved portion and a second curved portion, wherein the first curved portion has a first radius of curvature, wherein the second curved portion has a second radius of curvature, and wherein the first radius is different from the second radius.
42. The medium of clause 39, wherein the detector is shaped based on feature size, and a curvature of the mask feature that can be manufactured.
43. The medium of clause 39, wherein the curved portion of the detector has a shape and size corresponding to a curvature of a tip portion of the mask feature, and a minimum size of the mask feature that can be manufactured.
44. The medium of clause 39, wherein the detector is a single detector configured to determine MRC violations including a curvature violation and a width violation associated with the mask feature.
45. The medium of clause 39, wherein the detector is a single detector configured to determine MRC violations associated with a curvature violation and a space violation between at least two mask features.
46. The medium of any one of clauses 40-45, wherein the prescribed axis corresponds to a normal axis at the location, wherein the aligning comprises: determining the normal axis at the location of the mask feature; contacting an edge of the detector with an edge of the feature at the location; and orienting the orientation axis of the detector with the normal axis at the location of the feature.
47. The medium of any one of clauses 40-46, wherein identifying the MRC violation comprises: sliding the detector along an edge of the mask feature while maintaining the orientation axis of the detector aligned to a normal axis of each location of the mask feature.
48. The medium of clause 47, wherein identifying the MRC violation comprises:
   (a) aligning the orientation axis of the detector with a normal axis at a first location of the mask feature;
   (b) identifying, based on the aligned detector and the mask feature, whether a region of the mask feature around the first location is inside the enclosed area;
   (c) responsive to the region of the mask feature being inside the enclosed area, flagging the first location as the MRC location; and
   (d) responsive to the region of the mask feature not being inside the enclosed area, sliding the detector to a second location of the mask feature, and identifying the MRC violation by performing steps (a)-(c) at the second location.
49. The medium of any one of clauses 39-48, wherein the mask feature is curvilinear in shape.
50. The medium of any one of clauses 39-49, wherein the MRC comprises one or more geometric properties associated with the mask feature, the geometric properties comprising at least one of: a minimum CD of a mask feature that can be manufactured, a minimum curvature of mask feature that can be manufactured, or a minimum space between two features that can be manufactured.
51. The medium of any one of clauses 39-50, wherein the orientation axis extends inside or outside the enclosed area of the detector.
52. The medium of any one of clauses 39-51, wherein modifying the mask features comprise increasing or decreasing a size and/or a curvature of the portions of the mask features to satisfy the MRC using the detector.
53. The medium of any one of clauses 39-52, wherein modifying the mask features is an iterative process, each iteration comprising:
executing one or more process models associated with a patterning process using the modified mask features to generate target features to be printed on the semiconductor chip;
determining whether the target features satisfy design specification associated with the design layout;
and responsive to design specification not being satisfied, modifying the mask features to satisfy the design specification.
54. The medium of any one of clauses 39-53, wherein the enclosed area of the detector comprises: a fully enclosed area or a partially enclosed area having an opening.
55. A method for determining mask rule check violations associated with mask features, the method comprising:
obtaining a detector having geometric properties corresponding to a mask rule check (MRC), the detector configured to include a curved portion to detect a curvature violation, an enclosed area, a predefined orientation axis configured to guide relative positioning of the detector with a mask feature, and a length along the orientation axis to detect a critical dimension violation;
aligning the orientation axis of the detector with a prescribed axis at a location on the mask feature to cause the length of the detector to extend along the prescribed axis of the mask feature; and
identifying, based on the orientation axis of the detector aligned with the prescribed axis of the mask feature, an MRC violation corresponding to a region of the mask feature that intersects the enclosed area, wherein the aligning and geometry of the detector causes the detector to intersect the region of mask feature to identify the curvature violation, and/or the critical dimension violation.
56. The method of clause 55, wherein the detector is non-circular and has at least a first curved portion and a second curved portion, wherein the first curved portion has a first radius of curvature, wherein the second curved portion has a second radius of curvature, and wherein the first radius is different from the second radius.
57. The method of clause 56, wherein the non-circular detector is configured to have an elliptical shape having a radius of curvature configured to detect a curvature violation and a length along an orientation axis configured to detect a critical dimension violation.
58. The method of clause 57, wherein the curved portion of the detector has a shape and size corresponding to a curvature of a tip portion of the mask feature, and a minimum size of the mask feature defined by mask manufacturability check.
59. The method of clause 55, wherein the identifying comprises:
determining MRC violations including a curvature violation and a critical dimension violation based on the intersection of the detector with the mask feature at a single position.
60. The method of clause 55, wherein the identifying comprises:
determining MRC violations associated with a curvature violation and a space violation based on intersection between at least two mask features at a single position.
61. The method of any one of clauses 55-60, wherein obtaining of the detector comprises: obtaining the length of the detector along the orientation axis, the length being a distance between points of intersection of the orientation axis with a boundary of the detector upon extending the orientation axis.
62. The method of any one of clauses 55-61, wherein the prescribed axis corresponds to the normal axis, wherein the aligning comprises:
identifying the normal axis at the location of the mask feature, the normal axis being perpendicular to a curved at the location of the mask feature;
contacting an edge of the detector with an edge of the feature at the location; and
orienting the orientation axis of the detector with the normal axis at the location of the feature.
63. The method of any one of clauses 55-62, wherein identifying the MRC violation comprises:
determining the MRC violation by sliding the detector along an edge of the mask feature while maintaining the orientation axis of the detector aligned to a normal axis at each location of the mask feature.
64. The method of clause 63, wherein identifying the MRC violation comprises:
   (a) aligning the orientation axis of the detector with a first normal axis at a first location of the mask feature;
   (b) identifying, based on the orientation axis of the detector aligned with the first normal axis of the mask feature, whether a region of the mask feature around the first location is inside the enclosed area;
   (c) responsive to the region of the mask feature being inside the enclosed area, flagging the first location as the MRC location; and
   (d) responsive to the region of the mask feature not being inside the enclosed area, sliding the detector to a second location of the mask feature, and identifying the MRC violation by performing steps (a)-(c) at the second location and a second normal axis thereof.
65. The method of any one of clauses 55-64, wherein the obtaining of the detector comprises:
   accessing, from a library of detectors, the detector for determining MRC violation of the mask feature.
66. The method of clause 65, wherein the library of detectors include a plurality of detectors, each detector having a different shape and size than other detectors.
67. The method of any one of clauses 55-66, further comprising:
   performing, based on the detector, a mask design to determine shape and size of mask features of the mask design.
68. The method of clause 67, wherein performing of the mask design comprising:
   (a) simulating, using a design layout, a mask optimization process to determine the mask features for the mask design, the design layout corresponding to features to be printed on a semiconductor chip;
   (b) determining, via the detector, portions of the mask features that violate the MRC; and
   (c) responsive to violating the MRC, modifying the corresponding portions of the mask features to satisfy the MRC; and repeating steps (a)-(c).
69. The method of clause 68, the mask optimization process comprises: a mask only optimization process, a source mask optimization process, and/or an optical proximity correction process.
70. The method of any one of clauses 55-69, wherein the mask feature is curvilinear in shape.
71. The method of any one of clauses 55-70, wherein the MRC comprises one or more geometric properties associated with the mask feature, the geometric properties comprising at least one of: a minimum CD of a mask feature that can be manufactured, a minimum curvature of mask feature that can be manufactured, or a minimum space between two features that can be manufactured.
72. The method of any one of clauses 55-71, wherein the orientation axis is perpendicular to a point of the curved portion of the detector.
73. The method of any one of clauses 55-72, wherein the enclosed area of the detector comprises: a fully enclosed area or a partially enclosed area having an opening.
74. A method for determining mask rule check violations associated with mask features, the method comprising:
obtaining a non-circular detector having geometric properties corresponding to a mask rule check (MRC), the non-circular detector configured to include a curved portion to detect a curvature violation, an enclosed area, an orientation axis that is perpendicular to a point of the curved portion, and a length along the orientation axis to detect a critical dimension violation;
aligning the orientation axis with a prescribed axis of a location on a mask feature to cause the length of the non-circular detector to extend along the prescribed axis of the mask feature; and
identify, based on the aligned non-circular detector and the mask feature, an MRC violation corresponding to a region of the mask feature that intersects the enclosed area, wherein the aligning and geometry of the non-circular detector causes the detector to intersect the region of mask feature to identify the curvature violation, and/or the critical dimension violation.
75. The method of clause 74, wherein the non-circular detector has at least a first curved portion and a second curved portion, wherein the first curved portion has a first radius of curvature, wherein the second curved portion has a second radius of curvature, and wherein the first radius is different from the second radius.
76. The method of clause 75, wherein the non-circular detector is configured to have an elliptical shape with a radius of curvature configured to detect a curvature violation and a length along an orientation axis configured to detect a critical dimension violation.
77. The method of clause 74, wherein obtaining of the non-circular detector comprises:
receiving the detector that is shaped based on feature size, and a curvature of the mask feature that can be manufactured.
78. The method of clause 77, wherein the curved portion of the non-circular detector has a shape and size corresponding to a curvature of a tip portion of the mask feature, and a minimum size of the mask feature that can be manufactured.
79. The method of clause 74, wherein the identifying comprises:
determining MRC violations including a curvature violation and a critical dimension violation based on the intersection of the non-circular detector with the mask feature at a single position.
80. The method of clause 74, herein the identifying comprises:
determining MRC violations associated with a curvature violation and a space violation based on intersection between at least two mask features at a single position.
81. The method of any one of clause 74-80, wherein obtaining of the detector comprises:
obtaining the length of the detector along the orientation axis, the length being a distance between points of intersection of the orientation axis with a boundary of the detector upon extending the orientation axis.
82. The method of any one of clauses 74-81, wherein aligning comprises:
determining a normal axis at the location of the mask feature;
contacting an edge of the non-circular detector with an edge of the feature at the location; and
orienting the orientation axis of the non-circular detector with the normal axis at the location of the feature.
83. The method of any one of clauses 74-82, wherein identifying the MRC violation comprises: determining the MRC violation by sliding the non-circular detector along an edge of the mask feature while maintaining the orientation axis of the non-circular detector aligned to a normal axis of each location of the mask feature.
84. The method of clause 83, wherein identifying the MRC violation comprises:
   (a) aligning the orientation axis of the non-circular detector with a first normal axis at a first location of the mask feature;
   (b) identifying, based on the orientation axis of the detector aligned with the normal axis of the mask feature, whether a region of the mask feature around the first location is inside the enclosed area;
   (c) responsive to the region of the mask feature being inside the enclosed area, flagging the first location as the MRC location; and
   (d) responsive to the region of the mask feature not being inside the enclosed area, sliding the non-circular detector to a second location of the mask feature, and identifying the MRC violation by performing steps (a)-(c) at the second location and a second normal axis thereof.
85. The method of any one of clauses 74-84, wherein the obtaining of the non-circular detector comprises:
accessing, from a library of detectors, the non-circular detector for determining MRC violation of the mask feature.
86. The method of clause 85, wherein the library of detectors include a plurality of non-circular detectors, each non-circular detector having a different shape and size than other detectors.
87. The method of any one of clauses 74-86, wherein the mask feature is curvilinear in shape.
88. The method of any one of clauses 74-87, further comprising:
performing, based on the non-circular detector, a mask design to determine shape and size of mask features of the mask design.
89. The method of clause 88, wherein performing of the mask design comprising:
   (a) simulating, using a design layout, a mask optimization process to determine the mask features for the mask design, the design layout corresponding to features to be printed on a semiconductor chip;
   (b) determining, via the non-circular detector, portions of the mask features that violate the MRC; and
   (c) responsive to violating the MRC, modifying the corresponding portions of the mask features to satisfy the MRC; and repeating steps (a)-(c).
90. The method of clause 89, the mask optimization process comprises: a mask optimization process, a source mask optimization process, and/or an optical proximity correction process.
91. The method of any one of clauses 74-90, wherein the MRC comprises one or more geometric properties associated with the mask feature, the geometric properties comprising at least one of: a minimum CD of a mask feature that can be manufactured, a minimum curvature of mask feature that can be manufactured, or a minimum space between two features that can be manufactured.
92. The method of any one of clauses 74-91, wherein the enclosed area of the detector comprises:
a fully enclosed area or a partially enclosed area having an opening.
93. A method for determining a mask design for manufacturing a mask to be employed in a semiconductor manufacturing, the method comprising:
simulating, using a design layout, a mask optimization process to determine mask features for the mask design, the design layout corresponding to features to be printed on a semiconductor chip; and
determining, via a detector, portions of the mask features that violate a mask rule check (MRC), the detector configured to have a curved portion, an enclosed area, and an orientation axis that is perpendicular to a point of the curved portion, the orientation axis for guiding an orientation of the detector with respect to a mask feature to detect MRC violations; and responsive to the portions violating the MRC, modifying the corresponding portions of the mask features to satisfy the MRC.
94. The method of clause 93, the determining the portions of the mask features that violate the MRC comprises:
obtaining the detector having geometric properties corresponding to the MRC;
aligning the orientation axis with a normal axis of a location on a mask feature; and
identifying, based on the orientation axis of the detector and the normal axis of the mask feature, the MRC violation corresponding to a region of the mask feature that intersects the enclosed area.
95. The method of clause 93, wherein the detector is non-circular and has a first curved portion and a second curved portion, wherein the first curved portion has a first radius of curvature, wherein the second curved portion has a second radius of curvature, and wherein the first radius is different from the second radius.
96. The method of clause 93, wherein the detector is shaped based on feature size, and a curvature of the mask feature that can be manufactured.
97. The method of clause 93, wherein the curved portion of the detector has a shape and size corresponding to a curvature of a tip portion of the mask feature, and a minimum size of the mask feature that can be manufactured.
98. The method of clause 93, wherein the detector is a single detector configured to determine MRC violations including a curvature violation and a width violation associated with the mask feature.
99. The method of clause 93, wherein the detector is a single detector configured to determine MRC violations associated with a curvature violation and a space violation between at least two mask features.
100. The method of any one of clauses 94-99, wherein aligning the orientation axis of the detector with a normal axis of the mask feature comprises:
determining a normal axis at the location of the mask feature;
contacting an edge of the detector with an edge of the feature at the location; and orienting the orientation axis of the detector with the normal axis at the location of the feature.
101. The method of any one of clauses 94-100, wherein identifying the MRC violation comprises: sliding the detector along an edge of the mask feature while maintaining the orientation axis of the detector aligned to a normal axis of each location of the mask feature.
102. The method of clause 101, wherein identifying the MRC violation comprises:
   (a) aligning the orientation axis of the detector with a normal axis at a first location of the mask feature;
   (b) identifying, based on the aligned detector and the mask feature, whether a region of the mask feature around the first location is inside the enclosed area;
   (c) responsive to the region of the mask feature being inside the enclosed area, flagging the first location as the MRC location; and
   (d) responsive to the region of the mask feature not being inside the enclosed area, sliding the detector to a second location of the mask feature, and identifying the MRC violation by performing steps (a)-(c) at the second location.
103. The method of any one of clauses 93-102, wherein the mask feature is curvilinear in shape.
104. The method of any one of clauses 93-103, wherein the MRC comprises one or more geometric properties associated with the mask feature, the geometric properties comprising at least one of: a minimum CD of a mask feature that can be manufactured, a minimum curvature of mask feature that can be manufactured, or a minimum space between two features that can be manufactured.
105. The method of any one of clauses 93-104, wherein the orientation axis extends inside or outside the enclosed area of the detector.
106. The method of any one of clauses 93-105, wherein modifying the mask features comprise increasing or decreasing a size and/or a curvature of the portions of the mask features to satisfy the MRC using the detector.
107. The method of any one of clauses 93-106, wherein modifying the mask features is an iterative process, each iteration comprising:
executing one or more process models associated with a patterning process using the modified mask features to generate target features to be printed on the semiconductor chip;
determining whether the target features satisfy design specification associated with the design layout;
and responsive to design specification not being satisfied, modifying the mask features to satisfy the design specification.
108. The method of any one of clauses 93-107, wherein the enclosed area of the detector comprises: a fully enclosed area or a partially enclosed area having an opening.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The descriptions above are intended to be illustrative, not limiting. Thus, it will be apparent to one skilled in the art that modifications may be made as described without departing from the scope of the claims set out below.

1. A non-transitory computer-readable comprising instructions stored therein that, when executed by one or more processors, are configured to cause the one or more processors to at least:
obtain a non-circular detector having geometric properties corresponding to a mask rule check (MRC), the non-circular detector configured to include a curved portion to detect a curvature violation, include an enclosed area, include an orientation axis that is perpendicular to the curved portion, and include a length along the orientation axis to detect a critical dimension violation;
align the orientation axis with a prescribed axis of a location on a mask feature to cause the length of the non-circular detector to extend along the prescribed axis of the mask feature; and
identify, based on the aligned non-circular detector and the mask feature, an MRC violation corresponding to a region of the mask feature that intersects the enclosed area, wherein the alignment and geometry of the non-circular detector causes the detector to intersect the region of mask feature to identify a violation.

2. The medium of claim 1, wherein the non-circular detector has at least a first curved portion and a second curved portion, wherein the first curved portion has a first radius of curvature, wherein the second curved portion has a second radius of curvature, and wherein the first radius is different from the second radius.

3. The medium of claim 1, wherein the non-circular detector is configured to have an elliptical shape with a radius of curvature configured to detect a curvature violation.

4. The medium of claim 1, wherein the instructions configured to cause one or more processor to obtain the non-circular detector are further configured to cause the one or more processors to receive the detector that is defined based on feature size, and/or a curvature of the mask feature according to a manufacturability rule.

5. The medium of claim 1, wherein the curved portion of the non-circular detector has a shape and size corresponding to a curvature of a tip portion of the mask feature, and a minimum size of the mask feature according to a manufacturability rule.

6. The medium of claim 1, wherein the instructions configured to cause one or more processor to identify the MRC violation are further configured to cause the one or more processors to:
determine MRC violations including a curvature violation and a critical dimension violation based on the intersection of the non-circular detector with the mask feature at a single position; or
determine MRC violations associated with a curvature violation and a space violation based on intersection between at least two mask features at a single position.

7. The medium of claim 1, wherein the instructions configured to cause one or more processor to obtain the detector are further configured to cause the one or more processors to obtain the length of the detector along the orientation axis, the length being a distance between points of intersection of the orientation axis with a boundary of the detector upon extending the orientation axis.

8. The medium of claim 1, wherein the prescribed axis corresponds to a normal axis of the location on the mask feature, and wherein the instructions configured to cause one or more processor to align the orientation axis are further configured to cause the one or more processors to:
determine the normal axis at the location of the mask feature;
contact an edge of the non-circular detector with an edge of the feature at the location; and
orient the orientation axis of the non-circular detector with the normal axis at the location of the feature.

9. The medium of claim 1, wherein the instructions configured to cause one or more processor to identify the MRC violation are further configured to cause the one or more processors to determine the MRC violation by movement of the non-circular detector along an edge of the mask feature while maintaining the orientation axis of the non-circular detector aligned to a normal axis of each location of the mask feature.

10. The medium of claim 1, wherein the instructions configured to cause one or more processor to obtain the non-circular detector are further configured to cause the one or more processors to access, from a library of detectors, the non-circular detector for determining MRC violation of the mask feature, wherein the library of detectors include a plurality of different non-circular detectors.

11. The medium of claim 1, wherein the instructions are further configured to cause the one or more processors to:
perform, based on the non-circular detector, a mask design to determine shape and size of mask features, wherein performance of the mask design comprises:
(a) simulation of, using a design layout, a mask optimization to determine the mask features, the design layout corresponding to features to be printed for a semiconductor chip;
(b) determine, via the non-circular detector, portions of the mask features that violate the MRC; and
(c) responsive to of violating the MRC, modify the corresponding portions of the mask features to satisfy the MRC; and repeat (a)-(c).

12. The medium of claim 1, wherein the mask optimization comprises: a mask optimization process, a source mask optimization process, and/or an optical proximity correction process.

13. The medium of claim 1, wherein the MRC includes one or more geometric properties associated with the mask feature, the one or more geometric properties comprising at least one selected from: a minimum CD of a mask feature that can be manufactured, a minimum curvature of mask feature that can be manufactured, or a minimum space between two features that can be manufactured.

14. The medium of claim 1, wherein the enclosed area of the detector comprises a fully enclosed area or a partially enclosed area having an opening.

15. (canceled)

16. The medium of claim 1, wherein the mask feature is curvilinear in shape.

17. A non-transitory computer-readable comprising instructions stored therein that, when executed by one or more processors, are configured to cause the one or more processors to at least:
simulate, using a design layout, a mask optimization process to determine mask features for a mask design, the design layout corresponding to features to be printed for a semiconductor chip; and
determine, via a detector, a portion of the mask features that violates a mask rule check (MRC), the detector configured to have a curved portion, have an enclosed area, and have an orientation axis that is perpendicular to a point of the curved portion, the orientation axis for guiding an orientation of the detector with respect to a mask feature to detect an MRC violation; and
responsive to a portion violating the MRC, modify a corresponding portion of the mask features to satisfy the MRC.

18. The medium of claim 19, wherein the instructions configured to cause the one or more processors to determine the portion of the mask features that violates the MRC are further configured to cause the one or more processors to:
obtain the detector having geometric properties corresponding to the MRC;
align the orientation axis with a prescribed axis of a location on a mask feature; and
identify, based on the orientation axis of the detector and the prescribed axis of the mask feature, the MRC violation corresponding to a region of the mask feature that intersects the enclosed area.

19. The medium of claim 19, wherein the detector is non-circular and has a first curved portion and a second curved portion, wherein the first curved portion has a first radius of curvature, wherein the second curved portion has a second radius of curvature, and wherein the first radius is different from the second radius.

20. The medium of claim 19, wherein the detector is shaped based on feature size, and a curvature of the mask feature that can be manufactured.

21. The medium of claim 19, wherein the curved portion of the detector has a shape and size corresponding to a curvature of a tip portion of the mask feature, and a minimum size of the mask feature that can be manufactured.
